(19) United States
(12) Patent Application Publication
(10) Pub. No.: US 2026/0047315 A1
(43) Pub. Date: Feb. 12, 2026

(54) DISPLAY DEVICE, ELECTRONIC DEVICE INCLUDING THE SAME, AND METHOD OF MANUFACTURING THE SAME

(71) Applicant: Samsung Display Co., Ltd., Yongin-si (KR)

(72) Inventors: Kinyeng Kang, Yongin-si (KR); Sungeun Lee, Yongin-si (KR); Hyunho Kim, Yongin-sI (KR); Hyoengki Kim, Yongin-si (KR); Keunkyu Song, Yongin-si (KR)

(73) Assignee: Samsung Display Co., Ltd., Yongin-si (KR)

(21) Appl. No.: 19/226,890

(22) Filed: Jun. 3, 2025

(30) Foreign Application Priority Data
Aug. 7, 2024 (KR) 10-2024-0105746

(51) Int. Cl. H10K 59/80; H10K 59/12; H10K 59/122

(52) U.S. Cl. CPC H10K 59/80517; H10K 59/1201; H10K 59/122

(57) ABSTRACT

Provided is a display device including a substrate, a first pixel electrode and a second pixel electrode, which are arranged on the substrate to be spaced apart from each other, a first conductive layer, which is arranged on the substrate and includes a first-1 conductive opening that accommodates at least a portion of the first pixel electrode and a first-2 conductive opening that accommodates at least a portion of the second pixel electrode, and a second conductive layer, which is arranged on the first conductive layer and includes a second-1 conductive opening that overlaps the first-1 conductive opening and a second-2 conductive opening that overlaps the first-2 conductive opening.

### CROSS-REFERENCE TO RELATED APPLICATION

This application claims priority to and benefits of Korean Patent Application No. 10-2024-0105746 under 35 U.S.C. §119, filed on Aug. 7, 2024, in the Korean Intellectual Property Office, the entire contents of which are incorporated herein by reference.

### BACKGROUND

### 1. Technical Field

One or more embodiments relate to a device and a method, and more particularly, to a display device, an electronic device, and a method of manufacturing the display device.

### 2. Description of the Related Art

Electronic devices based on mobility have been widely used. In addition to small electronic devices, such as mobile phones, tablet personal computers (PCs) have been widely used recently as mobile electronic devices.

Such mobile electronic devices include display devices to provide visual information, such as images or videos, to users in order to support various functions. Recently, as components for driving display devices have become smaller, the proportion of display devices in electronic devices has gradually increased, and structures that may be bent to have a certain angle from a flat state have also been developed.

### SUMMARY

One or more embodiments include a display device in which the phenomenon of unintended leakage current flowing between multiple pixels is reduced.

Embodiments set forth herein are examples, and embodiments of the disclosure are not limited thereto.

Additional aspects will be set forth in part in the description which follows and, in part, will be apparent from the description, or may be learned by practice of the presented embodiments of the disclosure.

According to one or more embodiments, a display device includes a substrate, a first pixel electrode and a second pixel electrode, which are arranged on the substrate to be spaced apart from each other, a first conductive layer, which is arranged on the substrate and includes a first-1 conductive opening that accommodates at least a portion of the first pixel electrode and a first-2 conductive opening that accommodates at least a portion of the second pixel electrode, a second conductive layer, which is arranged on the first conductive layer and includes a second-1 conductive opening that overlaps the first-1 conductive opening and a second-2 conductive opening that overlaps the first-2 conductive opening, a bank layer, which is arranged on the second conductive layer and includes a first pixel opening that exposes at least a portion of the first pixel electrode, a second pixel opening that exposes at least a portion of the second pixel electrode, and a connection opening that exposes at least a portion of the second conductive layer, and a third conductive layer arranged on the bank layer and electrically connected to the second conductive layer through the connection opening.

The display device may further include a first-1 intermediate layer arranged on the first pixel electrode, a first charge generation layer arranged on the first-1 intermediate layer, a first-2 intermediate layer arranged on the first charge generation layer, a second-1 intermediate layer arranged on the second pixel electrode, a second charge generation layer arranged on the second-1 intermediate layer, a second-2 intermediate layer arranged on the second charge generation layer, and an opposite electrode arranged on the first-2 intermediate layer and the second-2 intermediate layer.

The first-1 intermediate layer may be spaced apart from the first-2 intermediate layer.

The first charge generation layer may be electrically connected to the second charge generation layer.

An end of the bank layer defining the first pixel opening may have an undercut structure.

In a cross-sectional view, the connection opening may be arranged between the first pixel opening and the second pixel opening.

The third conductive layer may include a third-1 conductive opening and a third-2 conductive opening, in a plan view, the third-1 conductive opening may surround the first pixel opening, and in a plan view, the third-2 conductive opening may surround the second pixel opening.

The first conductive layer may be electrically connected to a common voltage supply line.

The first conductive layer may be electrically connected to at least one of the first pixel electrode and the second pixel electrode.

According to one or more embodiments, an electronic device includes a substrate, a first pixel electrode and a second pixel electrode, which are arranged on the substrate to be spaced apart from each other, a first conductive layer, which is arranged on the substrate and includes a first-1 conductive opening that accommodates at least a portion of the first pixel electrode and a first-2 conductive opening that accommodates at least a portion of the second pixel electrode, a second conductive layer, which is arranged on the first conductive layer and includes a second-1 conductive opening that overlaps the first-1 conductive opening and a second-2 conductive opening that overlaps the first-2 conductive opening, a bank layer, which is arranged on the second conductive layer and includes a first pixel opening that exposes at least a portion of the first pixel electrode, a second pixel opening that exposes at least a portion of the second pixel electrode, and a connection opening that exposes at least a portion of the second conductive layer, and a third conductive layer arranged on the bank layer and electrically connected to the second conductive layer through the connection opening.

According to one or more embodiments, a method of manufacturing a display device includes arranging a first layer on a substrate, arranging a second layer on the first layer, patterning the first layer to form a first pixel electrode, a second pixel electrode, and a first conductive layer including a first-1 conductive opening and a first-2 conductive opening, patterning the second layer to form a second conductive layer including a second-1 conductive opening and a second-2 conductive opening and a sacrificial layer, arranging, on the second conductive layer, a bank layer including a first pixel opening, a second pixel opening, and a connection opening, arranging, on the bank layer, a third layer, at least a portion of which is accommodated in the connection opening, arranging, on the third layer, a photoresist layer overlapping the connection opening, patterning the third layer to form a third conductive layer including a third-1 conductive opening and a third-2 conductive opening, removing the sacrificial layer, and removing the photoresist layer.

The patterning of the first layer and the patterning of the second layer may be simultaneously performed, the first-1 conductive opening may overlap the second-1 conductive opening and accommodate at least a portion of the first pixel electrode, and the first-2 conductive opening may overlap the second-2 conductive opening and accommodate at least a portion of the second pixel electrode.

The method may further include arranging a first-1 intermediate layer on the first pixel electrode, arranging a second-1 intermediate layer on the second pixel electrode, arranging a charge generation layer on the first-1 intermediate layer and the second-1 intermediate layer, arranging a first-2 intermediate layer on the charge generation layer to overlap the first pixel electrode, arranging a second-2 intermediate layer on the charge generation layer to overlap the second pixel electrode, and arranging an opposite electrode on the first-2 intermediate layer and the second-2 intermediate layer.

An opposite electrode overlapping the first pixel electrode may be electrically connected to an opposite electrode overlapping the second pixel electrode.

In a plan view, the first-1 intermediate layer and the second-1 intermediate layer may be spaced apart from each other.

A charge generation layer overlapping the first pixel electrode may be electrically connected to a charge generation layer overlapping the second pixel electrode.

The third conductive layer may be electrically connected to the second conductive layer through the connection opening.

In a plan view, the third-1 conductive opening may surround the first pixel opening, and the third-2 conductive opening may surround the second pixel opening.

The first conductive layer may be electrically connected to a common voltage supply line.

The first conductive layer may be electrically connected to at least one of the first pixel electrode and the second pixel electrode.

According to one or more embodiments, an electronic device may include a substrate; a first pixel electrode and a second pixel electrode, which are arranged on the substrate to be spaced apart from each other; a first conductive layer, which is arranged on the substrate and includes a first-1 conductive opening that accommodates at least a portion of the first pixel electrode and a first-2 conductive opening that accommodates at least a portion of the second pixel electrode; a second conductive layer, which is arranged on the first conductive layer and includes a second-1 conductive opening that overlaps the first-1 conductive opening and a second-2 conductive opening that overlaps the first-2 conductive opening; a bank layer, which is arranged on the second conductive layer and includes a first pixel opening that exposes at least a portion of the first pixel electrode, a second pixel opening that exposes at least a portion of the second pixel electrode, and a connection opening that exposes at least a portion of the second conductive layer; and a third conductive layer arranged on the bank layer and electrically connected to the second conductive layer through the connection opening.

The electronic device may further include: a first-1 intermediate layer arranged on the first pixel electrode; a first charge generation layer arranged on the first-1 intermediate layer; a first-2 intermediate layer arranged on the first charge generation layer; a second-1 intermediate layer arranged on the second pixel electrode; a second charge generation layer arranged on the second-1 intermediate layer; a second-2 intermediate layer arranged on the second charge generation layer; and an opposite electrode arranged on the first-2 intermediate layer and the second-2 intermediate layer.

The first-1 intermediate layer may be spaced apart from the first-2 intermediate layer.

The first charge generation layer may be electrically connected to and the second charge generation layer.

An end of the bank layer defining the first pixel opening may include an undercut structure.

In a cross-sectional view, the connection opening may be arranged between the first pixel opening and the second pixel opening.

The third conductive layer may include a third-1 conductive opening and a third-2 conductive opening, in a plan view, the third-1 conductive opening may surround the first pixel opening, and in a plan view, the third-2 conductive opening may surround the second pixel opening.

The electronic device may be at least one of a smart watch, a mobile phone, a smartphone, a portable computer, a tablet personal computer (PC), a watch phone, an automotive display, a smart glass, a portable multimedia player (PMP), a navigation system, an ultra-mobile computer.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic plan views of a display device according to an embodiment;

FIG. 3 is a schematic diagram of an equivalent circuit of a light-emitting diode and a pixel circuit connected thereto provided in one pixel of a display device according to an embodiment;

FIG. 4 is a schematic plan view of a portion of a display device according to an embodiment;

FIG. 5 is a schematic cross-sectional view of a portion of a display device according to an embodiment;

FIG. 6 is a schematic cross-sectional view of a portion of a display device according to an embodiment;

FIG. 7 is a schematic flowchart of a method of manufacturing a display device, according to an embodiment;

FIGS. 8 to 19 are schematic cross-sectional views of a portion of a display device according to an embodiment;

FIG. 20 is a schematic block diagram of an electronic device according to an embodiment; and

FIG. 21 is a schematic diagram of electronic devices according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when being described with reference to the drawings, the same or corresponding components are given the same reference numerals, and duplicate descriptions thereof will be omitted.

In the following embodiments, the terms first, second, etc. are not intended to be limiting, however are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is over or on top of another portion, this includes not only when it is directly on top of the other portion, but also when there are other films, areas, components, etc. arranged therebetween.

In the drawings, components may be exaggerated or reduced in size for ease of illustration. For example, the size and thickness of each configuration shown in the drawings are arbitrary for purposes of illustration and the disclosure is not necessarily limited to those shown.

In the following embodiments, the terms x-axis, y-axis, and z-axis are not limited to, however may be interpreted in a broad sense to include, three axes in a Cartesian coordinate system. For example, the x-axis, y-axis, and z-axis may be orthogonal to each other, however, may also refer to different directions that are not orthogonal to each other.

In some embodiments, a particular sequence of processes may be performed in a different order than that described. For example, two processes described in succession may be performed substantially simultaneously, or may be performed in the opposite order from the order described.

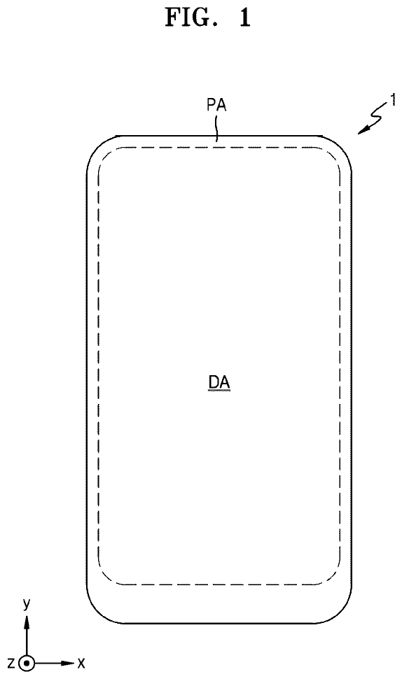

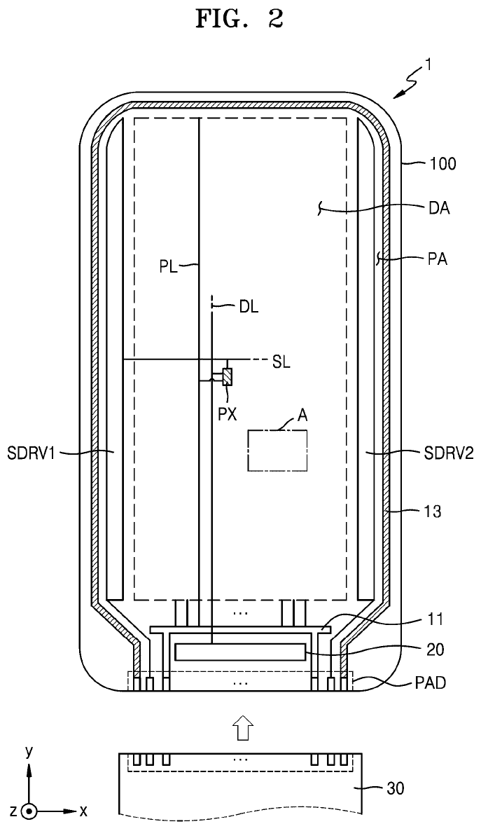

FIGS. 1 and 2 are schematic plan views of a display device 1 according to an embodiment.

Referring to FIG. 1, the display device 1 includes a display area DA and a peripheral area PA disposed outside of the display area DA. Because the display device 1 includes a substrate 100 in FIG. 2, the substrate 100 may include the display area DA and the peripheral area PA. In another embodiment, it may be understood that the display area DA and the peripheral area PA are defined on the substrate 100.

The display area DA is an area that displays an image, and multiple pixels may be arranged in the display area DA. The display area DA may have various shapes, such as a circle, an oval, a polygon, or a shape of a certain figure. FIG. 1 illustrates, for example, that the display area DA has a roughly rectangular shape with round corners.

The peripheral area PA may be arranged outside the display area DA. The peripheral area PA may be arranged to surround at least a portion of the display area DA.

Hereinafter, although an example in which the display device 1 according to an embodiment is an organic light-emitting display device is described, the disclosure is not limited thereto. In another embodiment, the display device 1 may be a display device, such as an inorganic light-emitting display device (or inorganic electroluminescence (EL) display device) or a quantum dot light-emitting display device. For example, an emission layer of a display element provided in the display device 1 may include an organic material, an inorganic material, quantum dots, an organic material and quantum dots, or an inorganic material and quantum dots.

The display device 1 may be an electronic device including a display panel. The electronic device may be a vehicle display device including a cluster, a center information display, and/or a passenger display, a wearable electronic device that may be worn on a part of a user's body, a medical electronic device, a robot, an electronic device for advertising or display, and/or an electronic device for education.

Referring to FIG. 2, the display device 1 may include the substrate 100. Various components forming the display device 1 may be arranged on the substrate 100. The substrate 100 may include a display area DA and a peripheral area PA outside the display area DA. In the specification, the fact that a component is located in the display area DA means that the component is arranged on the display area DA of the substrate 100 or overlaps the display area DA of the substrate 100. Likewise, in the specification, the fact that a component is located in the peripheral area PA means that the component is arranged on the peripheral area PA of the substrate 100 or overlaps the display area DA of the substrate 100.

Multiple pixels PX may be arranged in the display area DA. Each of the pixels PX may be implemented as a light-emitting diode, such as an organic light-emitting diode. Each of the pixels PX may emit, for example, red light, green light, blue light, or white light.

Pixel circuits driving the pixels PX may be electrically connected to signal lines or voltage lines for controlling the on/off and brightness of light-emitting diodes. For example, FIG. 2 illustrates a scan line SL extending in a first direction (e.g., the x-axis direction) and a data line DL extending in a second direction (e.g., the y-axis direction) as signal lines, and illustrates a driving voltage line PL as a voltage line.

The peripheral area PA may be a non-display area that does not display an image. The peripheral area PA may entirely surround the display area DA. The peripheral area PA may include external circuits for driving the pixels PX. For example, a first scan driver SDRV1, a second scan driver SDRV2, a data driver 20, a terminal portion PAD, a driving voltage supply line 11, and a common voltage supply line 13 may be arranged in the peripheral area PA.

The first scan driver SDRV1 may apply a scan signal to each of the pixel circuits that drive the pixels PX through a scan line SL. The second scan driver SDRV2 may be located on the opposite side of the first scan driver SDRV1 with the display area DA as the center and may be approximately parallel to the first scan driver SDRV1. Some of the pixel circuits of the pixels PX arranged in the display area DA may be electrically connected to the first scan driver SDRV1, and the rest may be electrically connected to the second scan driver SDRV2.

The data driver 20 may include an integrated circuit (e.g., a driving chip) that drives the display device 1. The integrated circuit may be a data driving integrated circuit that generates a data signal. However, the disclosure is not limited thereto. The data driver 20 may include multiple terminals. The data driver 20 may be electrically connected, through the terminals, to a printed circuit board 30 attached to one side of the display device 1. In another embodiment, the data driver 20 may be provided on the printed circuit board 30.

The terminal portion PAD may be arranged on one side of the substrate 100. The terminal portion PAD may be exposed without being covered by an insulating layer and may be electrically connected to the printed circuit board 30.

A controller (not shown) may be arranged on the printed circuit board 30. The controller may generate a control signal transmitted to the first scan driver SDRV1 and the second scan driver SDRV2. The controller may supply a driving voltage ELVDD to the driving voltage supply line 11 and may supply a common voltage ELVSS to the common voltage supply line 13. The driving voltage ELVDD may be applied to the pixel circuits of the pixels PX through the driving voltage line PL electrically connected to the driving voltage supply line 11, and the common voltage ELVSS may be applied to an opposite electrode of the light-emitting diode electrically connected to the common voltage supply line 13. The driving voltage supply line 11 may be provided to extend in the first direction (e.g., the x-axis direction) from the lower side of the display area DA. The common voltage supply line 13 may have a loop shape with one side open and may partially surround the display area DA.

The controller may generate a data signal, and the generated data signal may be transmitted to the data line DL through the data driver 20. The data signal may be sequentially transmitted to pixels PX located in the same column through data lines DL extending in a second direction (e.g., the y-axis direction). The controller may generate a touch driving signal transmitted to each of the sensor electrodes of a touch sensor layer.

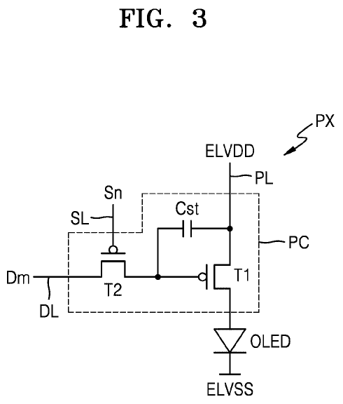

FIG. 3 is a schematic diagram of an equivalent circuit of a light-emitting diode and a pixel circuit PC connected thereto provided in one pixel PX of a display device according to an embodiment.

Referring to FIG. 3, the pixel circuit PC may be electrically connected to a light-emitting diode, such as an organic light-emitting diode OLED, to implement light emission of the pixel PX. The pixel circuit PC may include a driving thin-film transistor T1, a switching thin-film transistor T2, and a storage capacitor Cst. The switching thin-film transistor T2 may be electrically connected to a scan line SL and a data line DL, and may transfer a data signal Dm input through the data line DL to the driving thin-film transistor T1 according to a scan signal Sn input through the scan line SL.

The storage capacitor Cst may be electrically connected to the switching thin-film transistor T2 and a driving voltage line PL, and stores a voltage corresponding to the difference between a voltage received from the switching thin-film transistor T2 and a driving voltage ELVDD supplied to the driving voltage line PL.

The driving thin-film transistor T1 may be electrically connected to the driving voltage line PL and the storage capacitor Cst, and may control a driving current flowing from the driving voltage line PL to the organic light-emitting diode OLED in response to a voltage value stored in the storage capacitor Cst. The organic light-emitting diode OLED may emit light having a certain brightness by the driving current.

The pixel circuit PC may not be limited to the number of thin-film transistors and storage capacitors and the circuit design, described with reference to FIG. 3, and the number and the circuit design may be changed in various ways. For example, the number of thin-film transistors may be more than three or less than three, and the number of the storage capacitors may be more than one.

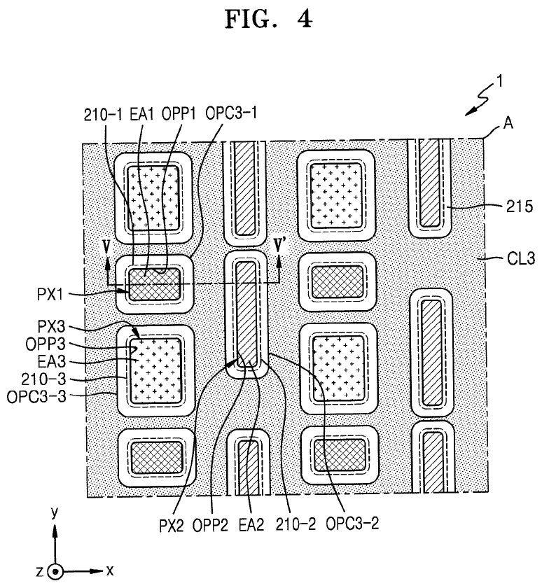

FIG. 4 is a schematic plan view of a portion of a display device 1 according to an embodiment. For example, FIG. 4 is a schematic plan view of an enlarged area A of FIG. 2. As depicted in FIG. 4, a plan view on a third conductive layer CL3 is illustrated for convenience.

As illustrated in FIG. 4, the display device 1 may include multiple pixels PX (see FIG. 2). Multiple pixels PX may include a first pixel PX1, a second pixel PX2, and a third pixel PX3. The first pixel PX1, the second pixel PX2, and the third pixel PX3 may be pixels that emit light of different colors. For example, the first pixel PX1 may be a pixel that emits red light, the second pixel PX2 may be a pixel that emits blue light, and the third pixel PX3 may be a pixel that emits green light. The red light may be light belonging to a wavelength band of about 580 nm to about 780 nm, the blue light may be light belonging to a wavelength band of about 400 nm to about 495 nm, and the green light may be light belonging to a wavelength band of about 495 nm to about 580 nm.

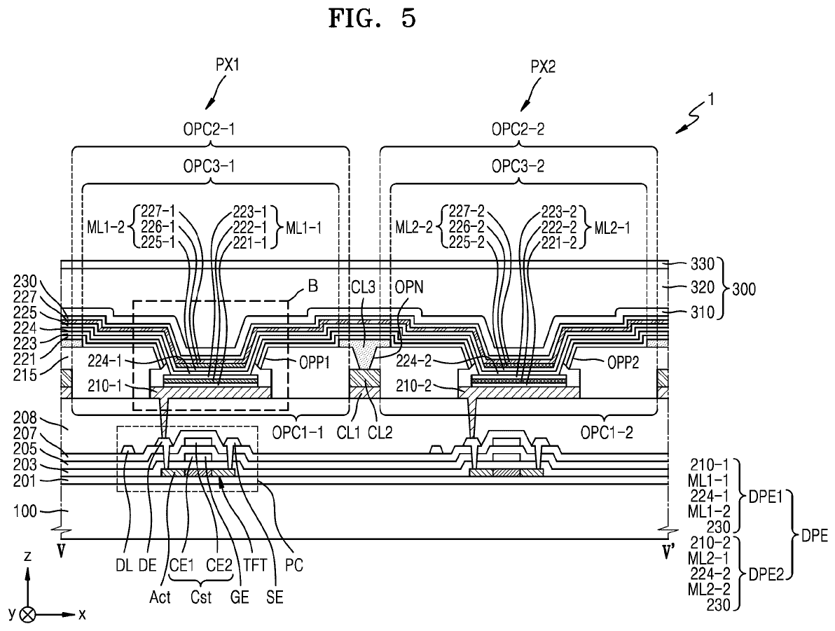

Each of multiple pixels PX may include a first display element DPE1 (see FIG. 5), a second display element DPE2 (see FIG. 5), or a third display element. For example, the first pixel PX1 may include the first display element DPE1, the second pixel PX2 may include the second display element DPE2, and the third pixel PX3 may include the third display element.

The first display element DPE1 (see FIG. 5), the second display element DPE2 (see FIG. 5), and the third display element may each include a pixel electrode, an opposite electrode, and an intermediate layer arranged therebetween.

Accordingly, the first pixel PX1 may include a first pixel electrode 210-1, the second pixel PX2 may include a second pixel electrode 210-2, and the third pixel PX3 may include a third pixel electrode 210-3. The first pixel electrode 210-1, the second pixel electrode 210-2, and the third pixel electrode 210-3 may be arranged spaced apart from each other on the substrate 100 (see FIG. 5) in the first direction and the second direction (e.g., x-axis direction and y-axis direction). In the specification, “in a plan view” means a plane viewed in a direction perpendicular to the substrate 100. For example, “A and B spaced apart from each other in a plan view” means “A and B spaced apart from each other when viewed in a direction perpendicular to the substrate 100 (e.g., in a plan view).

A bank layer 215 may be arranged above the first pixel electrode 210-1, the second pixel electrode 210-2, and the third pixel electrode 210-3. For example, the bank layer 215 may include a first pixel opening OPP1 exposing a central portion of the first pixel electrode 210-1, a second pixel opening OPP2 exposing a central portion of the second pixel electrode 210-2, and a third pixel opening OPP3 exposing a central portion of the third pixel electrode 210-3.

Although not shown in FIG. 4, emission layers emitting light may be respectively located in the first pixel opening OPP1, the second pixel opening OPP2, and the third pixel opening OPP3 of the bank layer 215. Opposite electrodes may be respectively arranged on the emission layers. As described above, a structure in which a pixel electrode, an emission layer, and an opposite electrode are stacked may form one display element DPE (see FIG. 5). One opening of the bank layer 215 may correspond to one display element DPE and may define one emission area.

For example, an emission layer emitting red light may be arranged in the first pixel opening OPP1, and the first pixel PX1 may have a first emission area EA1 defined by the first pixel opening OPP1. Similarly, an emission layer emitting blue light may be arranged in the second pixel opening OPP2, and the second pixel PX2 may have a second emission area EA2 defined by the second pixel opening OPP2. Similarly, an emission layer emitting green light may be arranged in the third pixel opening OPP3, and the third pixel PX3 may have a third emission area EA3 defined by the third pixel opening OPP3.

For example, the first emission area EA1 may be defined by the first pixel opening OPP1, the second emission area EA2 may be defined by the second pixel opening OPP2, and the third emission area EA3 may be defined by the third pixel opening OPP3. Accordingly, the size of the area of the first pixel opening OPP1 may be the same as the size of the area of the first emission area EA1. The size of the area of the second pixel opening OPP2 may be the same as the size of the area of the second emission area EA2, and the size of the area of the third pixel opening OPP3 may be the same as the size of the area of the third emission area EA3. The distance between the first pixel opening OPP1 and the second pixel opening OPP2 may be the same as the distance between the first emission area EA1 and the second emission area EA2. The distance between the first pixel opening OPP1 and the third pixel opening OPP3 may be the same as the distance between the first emission area EA1 and the third emission area EA3, and the distance between the second pixel opening OPP2 and the third pixel opening OPP3 may be the same as the distance between the second emission area EA2 and the third emission area EA3.

Each of the first pixel opening OPP1, the second pixel opening OPP2, and the third pixel opening OPP3 may have a polygonal shape when viewed in a direction (the z-axis direction) perpendicular to the substrate 100 (e.g., in a plan view). For example, each of the first emission area EA1, the second emission area EA2, and the third emission area EA3 may have a polygonal shape when viewed in the direction (the z-axis direction) perpendicular to the substrate 100 (e.g., in a plan view). It is illustrated in FIG. 4 that each of the first emission area EA1, the second emission area EA2, and the third emission area EA3 has a quadrangular shape, for example, a quadrangular shape with round corners, when viewed in the direction (the z-axis direction) perpendicular to the substrate 100 (e.g., in a plan view). However, the disclosure is not limited thereto. For example, each of the first emission area EA1, the second emission area EA2, and the third emission area EA3 may have a circular shape or an oval shape when viewed in the direction (the z-axis direction) perpendicular to the substrate 100 (e.g., in a plan view).

The first pixel opening OPP1, the second pixel opening OPP2, and the third pixel opening OPP3 may have areas having different sizes. For example, as illustrated in FIG. 4, the area of the second pixel opening OPP2 may be less than the area of the third pixel opening OPP3. The area of the first pixel opening OPP1 may be less than or equal to the area of the third pixel opening OPP3. For example, the first emission area EA1, the second emission area EA2, and the third emission area EA3 may have areas having different sizes. For example, the area of the second emission area EA2 may be less than the area of the third emission area EA3. The area of the first emission area EA1 may be less than or equal to the area of the third emission area EA3. A detailed description of the areas of the first pixel opening OPP1, the second pixel opening OPP2, and the third pixel opening OPP3 is given below.

The distance between the pixels PX may vary. The distance between the pixels PX refers to the distance between the emission areas of the pixels PX. For example, the distance between the pixels PX refers to the distance between openings respectively defining the emission areas. For example, the distance between the pixels PX refers to the distance between one side of one opening and one side of another opening located adjacent thereto. For example, the distance between the pixels PX refers to the distance between one side of one emission area and one side of another emission area located adjacent thereto.

FIG. 5 is a schematic cross-sectional view of a portion of a display device 1 according to an embodiment. For example, FIG. 5 is a schematic cross-sectional view illustrating a cross-section taken along line V-V′ of the display device 1 of FIG. 4.

Referring to FIGS. 4 and 5, the display device 1 may include a substrate 100, a display element DPE, a bank layer 215, and an encapsulation layer 300.

The display element DPE may include a first display element DPE1, a second display element DPE2, and a third display element. However, for convenience of description, the following description will focus on the display element DPE including the first display element DPE1 and the second display element DPE2, as illustrated in FIG. 5.

The first display element DPE1 and the second display element DPE2 may be electrically connected to a pixel circuit PC so that light emission may be controlled. For example, because the structures of pixel circuits PC electrically connected to the first display element DPE1 and the second display element DPE2, respectively are the same, the following description will focus on one pixel circuit PC.

The display device 1 according to the embodiment may include the substrate 100. The substrate 100 may include various materials and be flexible or bendable. For example, the substrate 100 may include glass, metal, or polymer resin. The substrate 100 may include a polymer resin, such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin and a barrier layer including an inorganic material (e.g., silicon oxide, silicon nitride, or silicon oxynitride) between the two layers, and various modifications may be made.

The display element DPE and the pixel circuit PC may be arranged on the substrate 100. The pixel circuit PC may be electrically connected to the display element DPE. For example, a first pixel PX1 and a second pixel PX2 may be arranged on the substrate 100. Each of the first pixel PX1 and the second pixel PX2 may include a display element DPE. The display element DPE may be the first display element DPE1 or the second display element DPE2. For example, the first pixel PX1 may include the first display element DPE1, and the second pixel PX2 may include the second display element DPE2.

The pixel circuit PC may include multiple thin-film transistors TFT and a storage capacitor Cst. For convenience of illustration, one thin-film transistor TFT is illustrated in FIG. 5, and the thin-film transistor TFT may correspond to the driving thin-film transistor T1 (see FIG. 3) described above.

A buffer layer 201 including an inorganic material, such as silicon oxide, silicon nitride, and/or silicon oxynitride, may be arranged between the thin-film transistor TFT and the substrate 100. The buffer layer 201 may increase the smoothness of the upper surface of the substrate 100 or prevent or reduce impurities from the substrate 100 and the like from penetrating into a semiconductor layer Act of the thin-film transistor TFT.

As illustrated in FIG. 5, the thin-film transistor TFT may have the semiconductor layer Act including amorphous silicon, polycrystalline silicon, an organic semiconductor material, or an oxide semiconductor material. The thin-film transistor TFT may include a gate electrode GE, a source electrode SE, and/or a drain electrode DE. The gate electrode GE may include various conductive materials and may have various layered structures, for example, may include a Mo layer and an Al layer. In another embodiment, the gate electrode GE may include a TiNX layer, an Al layer, and/or a Ti layer. The source electrode SE and the drain electrode DE may also include various conductive materials and may have various layered structures, for example, may include a Ti layer, an Al layer, and/or a Cu layer.

In order to secure insulation between the semiconductor layer Act and the gate electrode GE, a gate insulating layer 203 including an inorganic material, such as silicon oxide, silicon nitride, and/or silicon oxynitride, may be arranged between the semiconductor layer Act and the gate electrode GE. It is illustrated in FIG. 5 that the gate insulating layer 203 has a shape corresponding to the entire surface of the substrate 100 and has a structure in which contact holes are formed in preset portions. However, the disclosure is not limited thereto. For example, the gate insulating layer 203 may be patterned to have the same shape as the gate electrode GE.

A first interlayer insulating layer 205 including an inorganic material, such as silicon oxide, silicon nitride, and/or silicon oxynitride, may be arranged above the gate electrode GE. The first interlayer insulating layer 205 may have a single-layered or multi-layered structure including the aforementioned material. An insulating layer including an inorganic material may be formed through chemical vapor deposition (CVD) or atomic layer deposition (ALD). This also applies to embodiments and modifications thereof described below.

The storage capacitor Cst may include a first electrode CE1 and a second electrode CE2 that overlap each other with the first interlayer insulating layer 205 therebetween. The storage capacitor Cst may overlap the thin-film transistor TFT. In this regard, FIG. 5 illustrates that the gate electrode GE of the thin-film transistor TFT is the first electrode CE1 of the storage capacitor Cst. However, the disclosure is not limited thereto. For example, the storage capacitor Cst may not overlap the thin-film transistor TFT. The second electrode CE2 of the storage capacitor Cst may include a conductive material including molybdenum (Mo), aluminum (Al), copper (Cu), titanium (Ti), etc., and may have a multi-layered or single-layered structure including the conductive material.

A second interlayer insulating layer 207 including an inorganic material, such as silicon oxide, silicon nitride, and/or silicon oxynitride, may be arranged above the second electrode CE2 of the storage capacitor Cst. The second interlayer insulating layer 207 may have a single-layered or multi-layered structure including the aforementioned material.

The source electrode SE and the drain electrode DE may be arranged on the second interlayer insulating layer 207. A data line DL may be located on the same layer as the source electrode SE and the drain electrode DE and may include the same material as the source electrode SE and the drain electrode DE. The source electrode SE, the drain electrode DE, and the data line DL may include a material having excellent conductivity. The source electrode SE and the drain electrode DE may include a conductive material including molybdenum (Mo), aluminum (Al), copper (Cu), titanium (Ti), etc., and may have a multi-layered or single-layered structure including the conductive material. For example, the source electrode SE, the drain electrode DE, and the data line DL may each have a multi-layer structure including Ti/Al/Ti layers.

However, the disclosure is not limited thereto. For example, the thin-film transistor TFT may have only one of the source electrode SE and the drain electrode DE, or may not have both of them. For example, one thin-film transistor TFT may not have a drain electrode DE, and another thin-film transistor TFT electrically connected to the thin-film transistor TFT may not have a source electrode SE, and the semiconductor layers Act of two thin-film transistors may be electrically connected to each other. This connection structure may have the same effect as when one thin-film transistor TFT has a source electrode SE and another thin-film transistor TFT has a drain electrode DE, and the source electrode SE of one thin-film transistor TFT is electrically connected to the drain electrode DE of the other thin-film transistor TFT.

As illustrated in FIG. 5, a planarization layer 208 may be disposed on the second interlayer insulating layer 207 to cover the thin-film transistor TFT and the storage capacitor Cst. The planarization layer 208 may include an organic insulating material. For example, the planarization layer 208 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a mixture thereof, or the like. Although not shown in FIG. 5, a third interlayer insulating layer (not shown) may be further arranged under the planarization layer 208. The third interlayer insulating layer may include an inorganic insulating material, such as silicon oxide, silicon nitride, or silicon oxynitride.

The first display element DPE1 and the second display element DPE2 may be arranged spaced apart from each other on the planarization layer 208. For example, the first display element DPE1 and the second display element DPE2 may be arranged adjacent to each other in a first direction (e.g., x-axis direction) on the planarization layer 208. The first display element DPE1 and the second display element DPE2 may emit light of different colors. For example, the first display element DPE1 may emit any one of red light, blue light, and green light. The second display element DPE2 may emit any one of red light, blue light, and green light.

The first display element DPE1 may include a first pixel electrode 210-1, a first-1 intermediate layer ML1-1 , a first charge generation layer 224-1, a first-2 intermediate layer ML1-2 , and an opposite electrode 230. The first-1 intermediate layer ML1-1 may be arranged on the first pixel electrode 210-1, the first charge generation layer 224-1 may be arranged on the first-1 intermediate layer ML1-1 , the first-2 intermediate layer ML1-2 may be arranged on the first charge generation layer 224-1, and the opposite electrode 230 may be arranged on the first-2 intermediate layer ML1-2 in a third direction (e.g., z-axis direction or thickness direction).

The second display element DPE2 may include a second pixel electrode 210-2, a second-1 intermediate layer ML2-1, a second charge generation layer 224-2, a second-2 intermediate layer ML2-2, and an opposite electrode 230. The second-1 intermediate layer ML2-1 may be arranged on the second pixel electrode 210-2, the second charge generation layer 224-2 may be arranged on the second-1 intermediate layer ML2-1, the second-2 intermediate layer ML2-2 may be arranged on the second charge generation layer 224-2, and the opposite electrode 230 may be arranged on the second-2 intermediate layer ML2-2 in the third direction (e.g., z-axis direction or thickness direction).

The first pixel electrode 210-1 and the second pixel electrode 210-2 respectively provided in the first display element DPE1 and the second display element DPE2 may be provided by being patterned for each pixel. The opposing electrodes 230 of the first display element DPE1 and the second display element DPE2 may be integrally provided as a single body across the first display element DPE1 and the second display element DPE2.

The first pixel electrode 210-1 and the second pixel electrode 210-2 may be arranged to be spaced apart from each other on the substrate 100. For example, the first pixel electrode 210-1 and the second pixel electrode 210-2 may be arranged to be spaced apart from each other on the planarization layer 208. For example, the second pixel electrode 210-2 may be arranged to be adjacent to the first pixel electrode 210-1 in the first direction (e.g., x-axis direction) on the planarization layer 208.

Each of the first pixel electrode 210-1 and the second pixel electrode 210-2 may include a light-transmitting conductive layer including a light-transmitting conductive oxide, such as ITO, In₂O₃ or IZO, and a reflective layer including a metal, such as Al or Ag. For example, each of the first pixel electrode 210-1 and the second pixel electrode 210-2 may have a three-layered structure including ITO/Ag/ITO layers.

Each of the first pixel electrode 210-1 and the second pixel electrode 210-2 may be electrically connected to a thin-film transistor TFT by contacting one of the source electrode SE and the drain electrode DE, as illustrated in FIG. 5. For example, each of the first pixel electrode 210-1 and the second pixel electrode 210-2 may contact one of the source electrode SE and the drain electrode DE through a contact hole formed in the planarization layer 208.

A first conductive layer CL1 may be arranged on the substrate 100. For example, the first conductive layer CL1 may be arranged on the planarization layer 208. The first conductive layer CL1 may be arranged on the same layer as the first pixel electrode 210-1 and the second pixel electrode 210-2. The thicknesses of the first conductive layer CL1, the first pixel electrode 210-1, and the second pixel electrode 210-2 may be the same in the third direction (e.g., z-axis direction or thickness direction).

The first conductive layer CL1 may include a first-1 conductive opening OPC1-1 and a first-2 conductive opening OPC1-2. The first-1 conductive opening OPC1-1 may accommodate at least a portion of the first pixel electrode 210-1. In a plan view, the first-1 conductive opening OPC1-1 may overlap the first pixel electrode 210-1. In a plan view, the first-1 conductive opening OPC1-1 may be arranged to surround the first pixel electrode 210-1. The second-1 conductive opening OPC2-1 may accommodate at least a portion of the second pixel electrode 210-2. In a plan view, the second-1 conductive opening OPC2-1 may overlap the second pixel electrode 210-2. In a plan view, the second-1 conductive opening OPC2-1 may be arranged to surround the second pixel electrode 210-2.

The first conductive layer CL1 may include the same material as the first pixel electrode 210-1 and the second pixel electrode 210-2. For example, the first conductive layer CL1 may include a light-transmitting conductive layer including a light-transmitting conductive oxide, such as ITO, In₂O₃, or IZO, and a reflective layer including a metal, such as Al or Ag. For example, the first conductive layer CL1 may have a three-layered structure including ITO/Ag/ITO layers.

The second conductive layer CL2 may be arranged on the first conductive layer CL1. The second conductive layer CL2 may be in contact with the first conductive layer CL1. The second conductive layer CL2 may be electrically connected to the first conductive layer CL1. The second conductive layer CL2 may include a second-1 conductive opening OPC2-1 and a second-2 conductive opening OPC2-2.

The second-1 conductive opening OPC2-1 may overlap the first-1 conductive opening OPC1-1. The width of the second-1 conductive opening OPC2-1 may be the same as the width of the first-1 conductive opening OPC1-1 in the first direction (e.g., x-axis direction). In a plan view, the second-1 conductive opening OPC2-1 may overlap the first pixel electrode 210-1. In a plan view, the second-1 conductive opening OPC2-1 may be arranged to surround the first pixel electrode 210-1. The second-2 conductive opening OPC2-2 may overlap the first-2 conductive opening OPC1-2. The width of the second-2 conductive opening OPC2-2 may be the same as the width of the first-2 conductive opening OPC1-2 in the first direction (e.g., x-axis direction). In a plan view, the second-2 conductive opening OPC2-2 may overlap the second pixel electrode 210-2. In a plan view, the second-2 conductive opening OPC2-2 may be arranged to surround the second pixel electrode 210-2.

For example, the second conductive layer CL2 may include an oxide of at least one material selected from the group consisting of indium (In), gallium (Ga), stannium (Sn), zirconium (Zr), vanadium (V), hafnium (Hf), cadmium (Cd), germanium (Ge), chromium (Cr), titanium (Ti), and zinc (Zn). For example, the second conductive layer CL2 may include Indium Gallium Zinc Oxide (IGZO), Zinc Tin Oxide (ZTO), or Zinc Indium Oxide (ZIO).

A bank layer 215 may be arranged on the planarization layer 208 and the second conductive layer CL2. The bank layer 215 may have an opening corresponding to the pixel PX, for example, an opening that exposes at least a central portion of a pixel electrode, thereby defining the pixel PX.

For example, the bank layer 215 may include a first pixel opening OPP1, a second pixel opening OPP2, and a connection opening OPN. The first pixel opening OPP1 may expose at least a portion of the first pixel electrode 210-1. The second pixel opening OPP2 may expose at least a portion of the second pixel electrode 210-2.

In a plan view, the connection opening OPN may overlap the second conductive layer CL2. The connection opening OPN may expose at least a portion of the second conductive layer CL2. For example, the connection opening OPN may expose at least a portion of the upper surface of the second conductive layer CL2. In a cross-sectional view, the connection opening OPN may be arranged between the first pixel opening OPP1 and the second pixel opening OPP2.

As illustrated in FIG. 5, the bank layer 215 may increase the distance between the edge of the first pixel electrode 210-1 and the opposite electrode 230 above the first pixel electrode 210-1. Similarly, the bank layer 215 may increase the distance between the edge of the second pixel electrode 210-2 and the opposite electrode 230. Therefore, the occurrence of arcs (e.g., electrical discharge) or the like at the edge of the first pixel electrode 210-1 or the edge of the second pixel electrode 210-2 may be prevented. The bank layer 215 may include an organic material, such as polyimide or hexamethyldisiloxane (HMDSO).

A third conductive layer CL3 may be arranged on the bank layer 215. The third conductive layer CL3 may be electrically connected to the second conductive layer CL2 through the connection opening OPN. The third conductive layer CL3 may be in contact with the second conductive layer CL2. For example, the first conductive layer CL1, the second conductive layer CL2, and the third conductive layer CL3 may be electrically connected to each other. The third conductive layer CL3 may include a third-1 conductive opening OPC3-1 and a third-2 conductive opening OPC3-2. As depicted in FIG. 4, the third conductive layer CL3 may include a third-3 conductive opening OPC3-3.

The third-1 conductive opening OPC3-1 may overlap the first-1 conductive opening OPC1-1 and the second-1 conductive opening OPC2-1. The width of the third-1 conductive opening OPC3-1 may be smaller than the width of the first-1 conductive opening OPC1-1 and the width of the second-1 conductive opening OPC2-1 in the x-axis direction. In a plan view, the third-1 conductive opening OPC3-1 may overlap the first pixel electrode 210-1. In a plan view, the third-1 conductive opening OPC3-1 may be arranged to surround the first pixel opening OPP1.

The third-2 conductive opening OPC3-2 may overlap the first-2 conductive opening OPC1-2 and the second-2 conductive opening OPC2-2. The width of the third-2 conductive opening OPC3-2 may be smaller than the width of the first-2 conductive opening OPC1-2 and the width of the second-2 conductive opening OPC2-2 in the x-axis direction. In a plan view, the third-2 conductive opening OPC3-2 may overlap the second pixel electrode 210-2. In a plan view, the third-2 conductive opening OPC3-2 may be arranged to surround the second pixel opening OPP2.

The third conductive layer CL3 may include the same material as the first pixel electrode 210-1 and the second pixel electrode 210-2. For example, the third conductive layer CL3 may include a light-transmitting conductive layer including a light-transmitting conductive oxide, such as ITO, In₂O₃ or IZO, and a reflective layer including a metal, such as Al or Ag. For example, the third conductive layer CL3 may have a three-layered structure including ITO/Ag/ITO layers.

In another embodiment, the third conductive layer CL3 may include the same material as the second conductive layer CL2. For example, the third conductive layer CL3 may include an oxide of at least one material selected from the group consisting of indium (In), gallium (Ga), stannium (Sn), zirconium (Zr), vanadium (V), hafnium (Hf), cadmium (Cd), germanium (Ge), chromium (Cr), titanium (Ti), and zinc (Zn). For example, the third conductive layer CL3 may include Indium Gallium Zinc Oxide (IGZO), Zinc Tin Oxide (ZTO), or Zinc Indium Oxide (ZIO).

The opposite electrode 230 may be arranged on the first pixel electrode 210-1. The opposite electrode 230 may be integrally provided as a single body across the first display element DPE1 and the second display element DPE2. Therefore, the opposite electrode 230 may also be arranged on the second pixel electrode 210-2. The opposite electrode 230 may also be arranged on the third conductive layer CL3. The opposite electrode 230 may include a light-transmitting conductive layer including ITO, In₂O₃ or IZO, and may also include a semi-transmitting layer including a metal, such as Al or Ag. For example, the opposite electrode 230 may be a semi-transmitting layer including Mg or Ag.

Each of the first display element DPE1 and the second display element DPE2 may have a tandem structure including multiple emission layers. Each of the first display element DPE1 and the second display element DPE2 may have a structure in which multiple emission layers are stacked, thereby improving color purity and light-emitting efficiency.

A first common layer 221 may be arranged on the bank layer 215, a second common layer 223 may be arranged on the first common layer 221, a charge generation layer 224 may be arranged on the second common layer 223, a third common layer 225 may be arranged on the charge generation layer 224, a fourth common layer 227 may be arranged on the third common layer 225, and an opposite electrode 230 may be arranged on the fourth common layer 227 in the third direction (e.g., z-axis direction).

A portion of the first common layer 221 arranged on the first pixel electrode 210-1 is referred to as a first-1 common layer 221-1, and a portion of the first common layer 221 arranged on the second pixel electrode 210-2 is referred to as a second-1 common layer 221-2.

A portion of the second common layer 223 arranged on the first-1 common layer 221-1 is referred to as a first-2 common layer 223-1, and a portion of the second common layer 223 arranged on the second-1 common layer 221-2 is referred to as a second-2 common layer 223-2. A first-1 emission layer 222-1 may be arranged between the first-1 common layer 221-1 and the first-2 common layer 223-1, and a second-1 emission layer 222-2 may be arranged between the second-1 common layer 221-2 and the second-2 common layer 223-2.

A portion of the charge generation layer 224 arranged on the first-2 common layer 223-1 is referred to as a first charge generation layer 224-1, and a portion of the charge generation layer 224 arranged on the second-2 common layer 223-2 is referred to as a second charge generation layer 224-2.

A portion of the third common layer 225 arranged on the first charge generation layer 224-1 is referred to as a first-3 common layer 225-1, and a portion of the third common layer 225 arranged on the second charge generation layer 224-2 is referred to as a second-3 common layer 225-2.

A portion of the fourth common layer 227 arranged on the first-3 common layer 225-1 is referred to as a first-4 common layer 227-1, and a portion of the fourth common layer 227 arranged on the second-3 common layer 225-2 is referred to as a second-4 common layer 227-2. A first-2 emission layer 226-1 may be arranged between the first-3 common layer 225-1 and the first-4 common layer 227-1, and a second-2 emission layer 226-2 may be arranged between the second-3 common layer 225-2 and the second-4 common layer 227-2.

The first-1 common layer 221-1, the first-1 emission layer 222-1, and the first-2 common layer 223-1 are collectively referred to as a first-1 intermediate layer, and the first-3 common layer 225-1, the first-2 emission layer 226-1, and the first-4 common layer 227-1 are collectively referred to as a first-2 intermediate layer. For example, the first-1 intermediate layer may include the first-1 common layer 221-1, the first-1 emission layer 222-1, and the first-2 common layer 223-1, and the first-2 intermediate layer may include the first-3 common layer 225-1, the first-2 emission layer 226-1, and the first-4 common layer 227-1. For example, the first display element DPE1 may include the first pixel electrode 210-1, the first-1 intermediate layer, the first charge generation layer 224-1, the first-2 intermediate layer, and the opposite electrode 230.

The second-1 common layer 221-2, the second-1 emission layer 222-2, and the second-2 common layer 223-2 are collectively referred to as a second-1 intermediate layer, and the second-3 common layer 225-2, the second-2 emission layer 226-2, and the second-4 common layer 227-2 are collectively referred to as a second-2 intermediate layer. For example, the second-1 intermediate layer may include the second-1 common layer 221-2, the second-1 emission layer 222-2, and the second-2 common layer 223-2, and the second-2 intermediate layer may include the second-3 common layer 225-2, the second-2 emission layer 226-2, and the second-4 common layer 227-2. For example, the second display element DPE2 may include the second pixel electrode 210-2, the second-1 intermediate layer, the second charge generation layer 224-2, the second-2 intermediate layer, and the opposite electrode 230.

The first-1 emission layer 222-1 and the second-1 emission layer 222-2 may be individually provided by being patterned separately for the first display element DPE1 and the second display element DPE2. The first-2 emission layer 226-1 and the second-2 emission layer 226-2 may be individually provided by being patterned separately for the first display element DPE1 and the second display element DPE2.

The first-1 emission layer 222-1 and the first-2 emission layer 226-1 may emit light of the same color. For example, the first-1 emission layer 222-1 and the first-2 emission layer 226-1 may each emit one of red light, blue light, and green light. The second-1 emission layer 222-2 and the second-2 emission layer 226-2 may emit light of the same color. For example, the second-1 emission layer 222-2 and the second-2 emission layer 226-2 may each emit one of red light, blue light, and green light.

The charge generation layer 224 may be provided in common across the first display element DPE1 and the second display element DPE2. The charge generation layer 224 may supply charges to the first-1 intermediate layer ML1-1 , the first-2 intermediate layer ML1-2 , the second-1 intermediate layer ML2-1, and the second-2 intermediate layer ML2-2. Accordingly, the light-emitting efficiency of each of the first display element DPE1 and the second display element DPE2 each having a structure in which multiple emission layers are stacked may be further increased.

The charge generation layer 224 may include an n-type charge generation layer for supplying electrons to the first-1 intermediate layer ML1-1 and the second-1 intermediate layer ML2-1. The charge generation layer 224 may include a p-type charge generation layer for supplying holes to the first-2 intermediate layer ML1-2 and the second-2 intermediate layer ML2-2.

The n-type charge generation layer may include an n-type dopant material and an n-type host material. The n-type dopant material may be a metal of Group 1 and Group 2 of the periodic table, an organic material capable of injecting electrons, or a mixture thereof. For example, the n-type dopant material may be any one of an alkali metal and an alkaline earth metal. For example, the n-type charge generation layer may include an organic layer doped with an alkali metal, such as lithium (Li), natrium (Na), potassium (K), or cesium (Cs), or an alkaline earth metal, such as magnesium (Mg), strontium (Sr), barium (Ba), or radium (Ra). However, the disclosure is not limited thereto. The n-type host material may include a material capable of transferring electrons, for example, one or more of Alq3(tris(8-hydroxyquinolino)aluminum), Liq(8-hydroxyquinolinolato-lithium), PBD(2-(4-biphenylyl)-5-(4-tert-butylphenyl)-1,3,4oxadiazole), TAZ(3-(4-biphenyl)4-phenyl-5-tert-butylphenyl-1,2,4-triazole), spiro-PBD, BAlq(bis(2-methyl-8-quinolinolate)-4-(phenylphenolato)aluminium), SAlq, TPBi(2,2′,2-(1,3,5-benzinetriyl)-tris(1-phenyl-1-H-benzimidazole), oxadiazole, triazole, phenanthroline, benzoxazole, and benzthiazole. However, the disclosure is not limited thereto.

The p-type charge generation layer may include a p-type dopant material and a p-type host material. The p-type dopant material may include an organic material, such as a metal oxide, tetrafluoro-tetracyanoquinodimethane (F4-TCNQ), hexaazatriphenylene-hexacarbonitrile (HAT-CN), or hexaazatriphenylene, or a metal material, such as V₂O₅, MoOₓ, WO₃, but is not limited thereto. The p-type host material may include a material capable of transferring holes, for example, one or more of NPD(N,N-dinaphthyl-N,N′-diphenyl benzidine)(N,N′-bis(naphthalene-1-yl)-N,N′-bis(phenyl)-2,2′-dimethylbenzidine), TPD(N,N′-bis-(3-methylphenyl)-N,N′-bis-(phenyl)-benzidine), and MTDATA(4,4′,4-Tris(N-3-methylphenyl-N-phenyl-amino)-triphenylamine). However, the disclosure is not limited thereto.

The first common layer 221 may be a single layer or a multilayer. For example, when the first common layer 221 is formed of a polymer material, the first common layer 221 may be a hole transport layer (HTL) having a single-layered structure and may include poly-(3,4)-ethylene-dihydroxy thiophene (PEDOT) or polyaniline (PANI). When the first common layer 221 is formed of a low molecular weight material, the first common layer 221 may include a hole injection layer (HIL) and a hole transport layer (HTL).

The second common layer 223 may not be provided and may be optional. The second common layer 223 may be a single layer or a multilayer. The second common layer 223 may include an electron transport layer (ETL) and/or an electron injection layer (EIL).

The third common layer 225 may be a single layer or a multilayer. For example, when the third common layer 225 is formed of a polymer material, the third common layer 225 may be an HTL having a single-layered structure and may include poly-(3,4)-ethylene-dihydroxy thiophene (PEDOT) or polyaniline (PANI). When the third common layer 225 is formed of a low molecular weight material, the third common layer 225 may include an HIL and an HTL.

The fourth common layer 227 may not be provided and may be optional. The fourth common layer 227 may be a single layer or a multilayer. The fourth common layer 227 may include an ETL and/or an EIL.

The first conductive layer CL1 may be electrically connected to a common voltage supply line 13 (see FIG. 2). For example, the first conductive layer CL1 may be electrically connected to the opposite electrode 230 in the peripheral area PA. Therefore, a common voltage ELVSS (see FIG. 3) may be applied to each of the first conductive layer CL1, the second conductive layer CL2, and the third conductive layer CL3.

In another embodiment, the first conductive layer CL1 may be electrically connected to at least one of the first pixel electrode 210-1 and the second pixel electrode 210-2. A voltage may be applied to each of the first conductive layer CL1, the second conductive layer CL2, and the third conductive layer CL3, like the first pixel electrode 210-1 or the second pixel electrode 210-2.

The third conductive layer CL3 and the charge generation layer 224 overlapping the third conductive layer CL3 can perform a capacitor function. A capacitance may be formed between the third conductive layer CL3 and the charge generation layer 224. In this structure, the first conductive layer CL1, the second conductive layer CL2, and the third conductive layer CL3 may absorb unintended lateral leakage current flowing along the charge generation layer 224. For example, the first conductive layer CL1, the second conductive layer CL2, and the third conductive layer CL3 may reduce the leakage current formed between the first charge generation layer 224-1 and the second charge generation layer 224-2. Therefore, the durability and quality of the display device 1 may be improved.

The first display element DPE1 and the second display element DPE2 may further include a capping layer (not shown) arranged on the outside of the opposite electrode 230. The capping layer may improve the light emission efficiency by the principle of constructive interference. As a result, the light extraction efficiency of the first display element DPE1 and the second display element DPE2 may increase, and thus, the light emission efficiency of the first display element DPE1 and the second display element DPE2 may be improved.

An encapsulation layer 300 may be arranged on the display element DPE. For example, an encapsulation layer 300 may be arranged on the opposite electrode 230. The encapsulation layer 300 may include at least one inorganic layer and at least one organic layer. For example, the encapsulation layer 300 may include a first inorganic encapsulation layer 310, an organic encapsulation layer 320, and a second inorganic encapsulation layer 330 that are sequentially stacked in the third direction (e.g., z-axis direction), but is not limited thereto and may have various configurations.

The first inorganic encapsulation layer 310 and the second inorganic encapsulation layer 330 may each include at least one selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride (SiON).

The organic encapsulation layer 320 may include at least one selected from the group consisting of an acrylic-based resin layer, a methacrylic-based resin layer, a polyisoprene-based resin layer, a vinyl-based resin layer, an epoxy-based resin layer, a urethane-based resin layer, a cellulose-based resin layer, and a perylene-based resin layer.

In the embodiment, various functional layers, such as a polarizing layer, a color filter layer, and a touch screen layer, may be further arranged above the encapsulation layer 300.

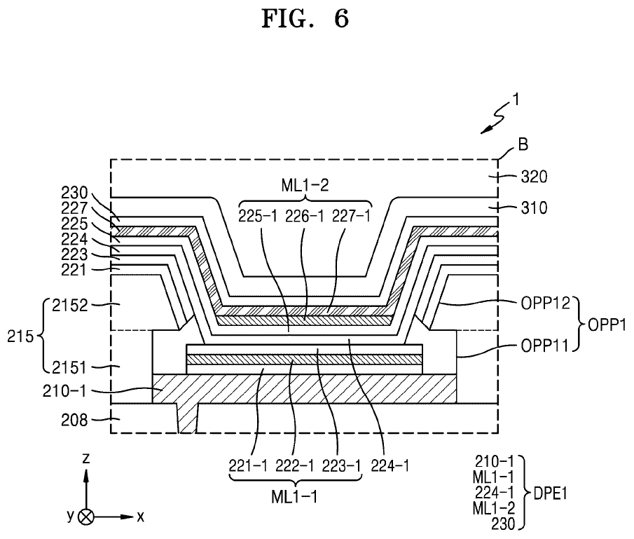

FIG. 6 is a schematic cross-sectional view of a portion of a display device 1 according to an embodiment.

For example, FIG. 6 is an enlarged view of an area B in FIG. 5. FIG. 6 focuses on the first display element DPE1 of the display device, but the same may apply to the second display element DPE2 (see FIG. 5).

Referring to FIGS. 5 and 6, an end of the bank layer 215 defining the first pixel opening OPP1 may have an undercut structure. Likewise, an end of the bank layer 215 defining the second pixel opening OPP2 may have an undercut structure.

The bank layer 215 may include a first bank layer 2151 and a second bank layer 2152. The first pixel opening OPP1 may include a first-1 pixel opening OPP11 arranged on the first bank layer 2151 and a first-2 pixel opening OPP12 arranged on the second bank layer 2152.

The second bank layer 2152 may be arranged on the first bank layer 2151. Therefore, the first-2 pixel opening OPP12 may be arranged on the first-1 pixel opening OPP11.

The first-1 pixel opening OPP11 may be in communication with the first-2 pixel opening OPP12. In a plan view, the first-2 pixel opening OPP12 may overlap the first-1 pixel opening OPP11.

At the boundary between the first-1 pixel opening OPP11 and the first-2 pixel opening OPP12, the width of the first-2 pixel opening OPP12 may be less than the width of the first-1 pixel opening OPP11. In a direction away from the first pixel electrode 210-1, the width of the first pixel opening OPP1 may discontinuously decrease at a specified height.

The width of the first pixel electrode 210-1 may be the same as the width of the first pixel opening OPP1 in a plan view. For example, the width of the first pixel electrode 210-1 may be the same as the width of the first-1 pixel opening OPP11 in a plan view. The side of the first pixel electrode 210-1 may be in contact with the bank layer 215. For example, the side of the first pixel electrode 210-1 may be in contact with the first bank layer 2151. Similarly, the width of the second pixel electrode 210-2 may be the same as the width of the second pixel opening OPP2.

Due to the undercut structure of the bank layer 215, the first-1 intermediate layer ML1-1 may be spaced apart from the first-2 intermediate layer ML1-2. The first common layer 221 and the second common layer 223 may be cut off at the boundary of the undercut structure of the bank layer 215. However, the first charge generation layer 224-1 arranged on the first-1 intermediate layer ML1-1 and the second charge generation layer 224-2 arranged on the second-1 intermediate layer ML2-1 may be electrically connected to each other. The third common layer 225 and the fourth common layer 227 arranged on the charge generation layer may each be integrally formed as a single body across the first display element DPE1 and the second display element DPE2. The opposite electrode 230 arranged on the fourth common layer 227 may be integrally formed as a single body across the first display element DPE1 and the second display element DPE2.

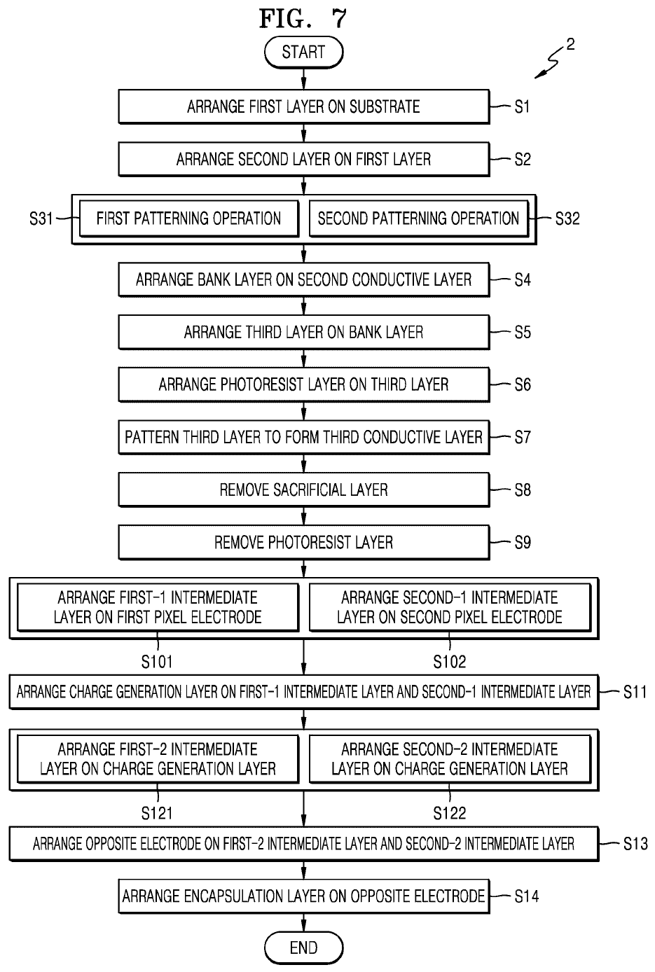

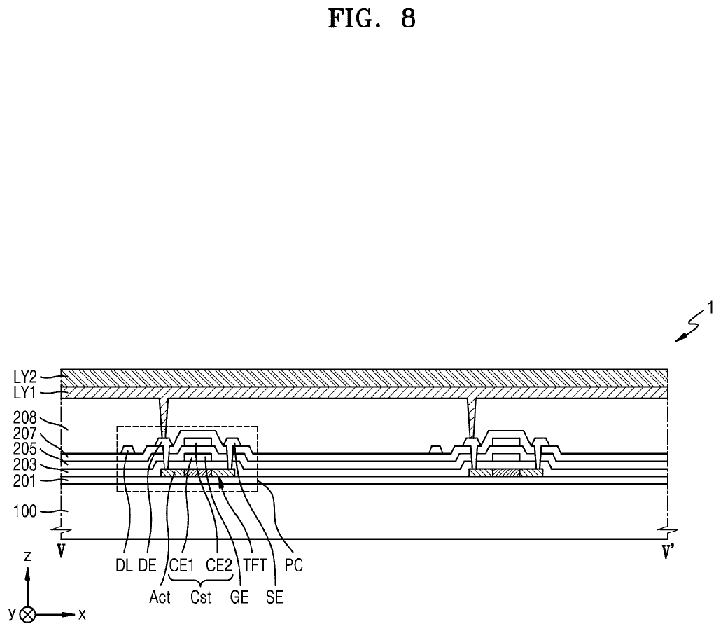

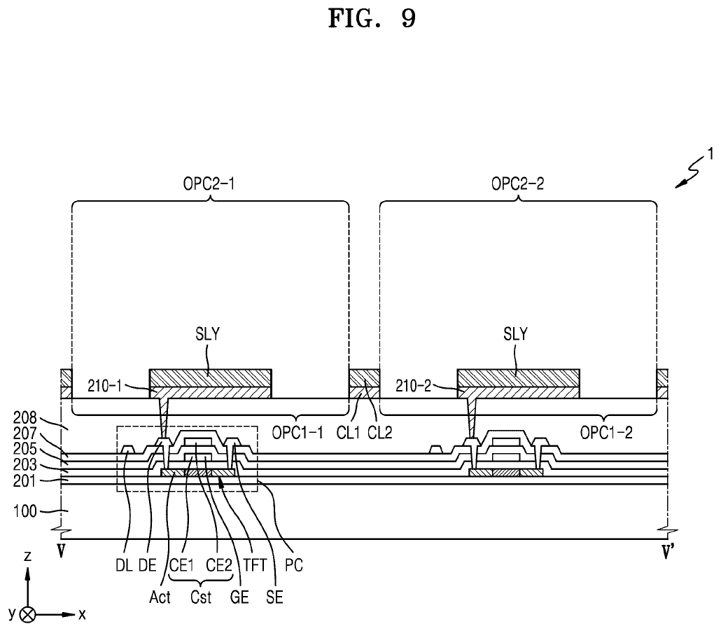

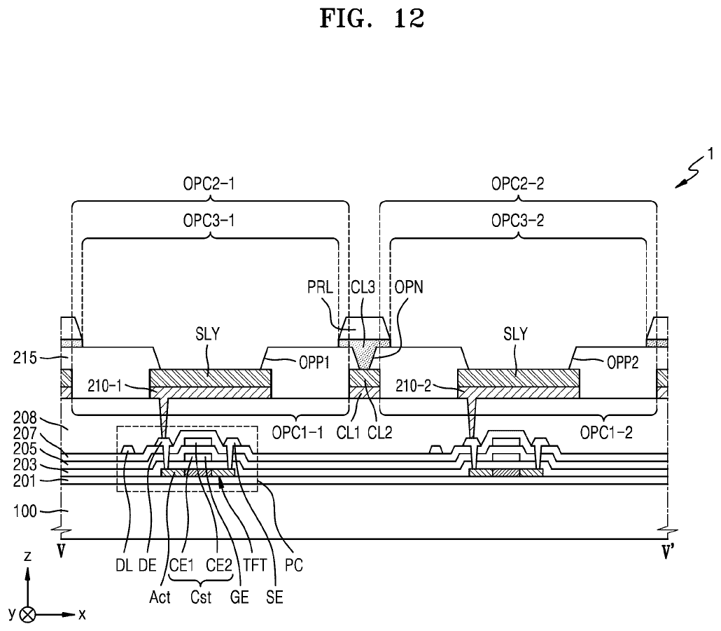

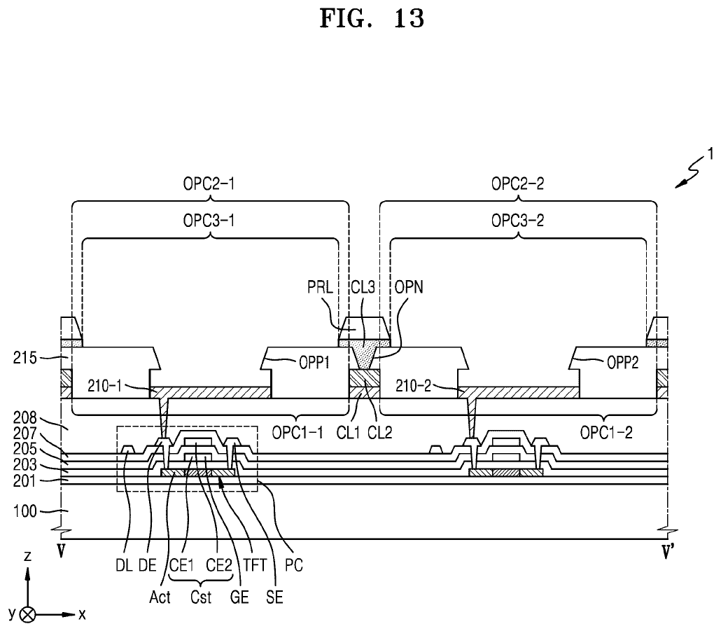

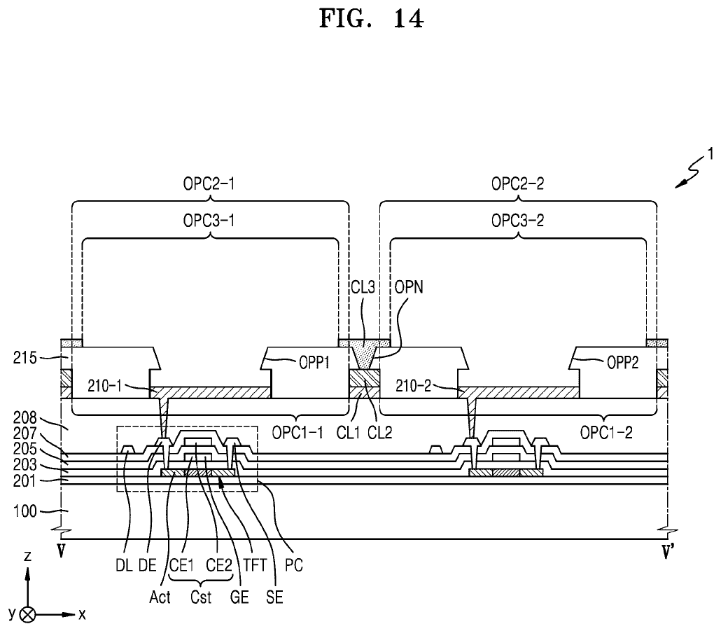

FIG. 7 is a schematic flowchart of a method 2 of manufacturing a display device, according to an embodiment, and FIGS. 8 to 19 are schematic cross-sectional views of a portion of a display device 1 according to an embodiment.

As depicted in FIGS. 7 to 19, the same reference numerals as those in FIGS. 1 to 6 refer to the same members as those in FIGS. 1 to 6, and thus, redundant descriptions thereof are omitted.

Referring to FIGS. 7 to 19, a pixel circuit PC may be arranged on a substrate 100. The pixel circuit PC may include a thin-film transistor TFT and a storage capacitor Cst. The thin-film transistor TFT may include a semiconductor layer Act, a gate electrode GE, a source electrode SE, and/or a drain electrode DE. A buffer layer 201 may be arranged between the thin-film transistor TFT and the substrate 100. A gate insulating layer 203 may be arranged between the semiconductor layer Act and the gate electrode GE. A first interlayer insulating layer 205 may be arranged above the gate electrode GE. The storage capacitor Cst may include a first electrode CE1 and a second electrode CE2 that overlap each other with the first interlayer insulating layer 205 therebetween. The source electrode SE and the drain electrode DE may be arranged on a second interlayer insulating layer 207. A data line DL may be located on the same layer as the source electrode SE and the drain electrode DE. A planarization layer 208 may be arranged to cover the thin-film transistor TFT and the storage capacitor Cst.

Referring to FIGS. 7 and 8, the method 2 of manufacturing a display device may include an operation S1 of arranging a first layer LY1 on a substrate 100, and an operation S2 of arranging a second layer LY2 on the first layer LY1.

The first layer LY1 may cover (e.g., entirely cover) the substrate 100. For example, the first layer LY1 may be arranged on the planarization layer 208. The first layer LY1 may be electrically connected to the thin-film transistor TFT by contacting one of the source electrode SE and the drain electrode DE. For example, the first layer LY1 may be in contact with one of the source electrode SE and the drain electrode DE through a contact hole formed in the planarization layer 208.

The first layer LY1 may include the same material as the first pixel electrode 210-1, the second pixel electrode 210-2, and the first conductive layer CL1, described with reference to FIG. 5. For example, the first layer LY1 may include a light-transmitting conductive layer including a light-transmitting conductive oxide, such as ITO, In₂O₃ or IZO, and a reflective layer including a metal, such as Al or Ag. For example, the first layer LY1 may have a three-layered structure including ITO/Ag/ITO layers.

The second layer LY2 may cover (e.g., entirely cover) the substrate 100. For example, the second layer LY2 may be arranged on the first layer LY1. The second layer LY2 may be electrically connected to the first layer LY1. The second layer LY2 may be in contact with the first layer LY1.

The second layer LY2 may include the same material as the second conductive layer CL2 described with reference to FIG. 5. For example, the second layer LY2 may include an oxide of at least one material selected from the group consisting of indium (In), gallium (Ga), stannium (Sn), zirconium (Zr), vanadium (V), hafnium (Hf), cadmium (Cd), germanium (Ge), chromium (Cr), titanium (Ti), and zinc (Zn). For example, the second layer LY2 may include Indium Gallium Zinc Oxide (IGZO), Zinc Tin Oxide (ZTO), or Zinc Indium Oxide (ZIO).

Referring to FIGS. 7 to 9, the method 2 of manufacturing a display device may include a first patterning operation S31 and a second patterning operation S32.

The first patterning operation S31 may be an operation of patterning the first layer LY1 to form a first pixel electrode 210-1, a second pixel electrode 210-2, and a first conductive layer CL1. For example, the first conductive layer CL1 may include a first-1 conductive opening OPC1-1 and a first-2 conductive opening OPC1-2.

The second patterning operation S32 may be an operation of patterning the second layer LY2 to form a second conductive layer CL2 and a sacrificial layer SLY. For example, the second conductive layer CL2 may include a second-1 conductive opening OPC2-1 and a second-2 conductive opening OPC2-2.

The first patterning operation S31 and the second patterning operation S32 may be simultaneously performed in one process. The first patterning operation S31 and the second patterning operation S32 may be performed by a photolithography process. Each of the first conductive layer CL1 and the second conductive layer CL2 may be formed by wet etching, dry etching, or a combination thereof. A known method may be used as the photolithography process.

In a plan view, the first-1 conductive opening OPC1-1 may overlap the second-1 conductive opening OPC2-1. In a plan view, the first-2 conductive opening OPC1-2 may overlap the second-2 conductive opening OPC2-2. The width of the first-1 conductive opening OPC1-1 may be the same as the width of the second-1 conductive opening OPC2-1. The width of the first-2 conductive opening OPC1-2 may be the same as the width of the second-2 conductive opening OPC2-2. In a plan view, each of the first pixel electrode 210-1 and the second pixel electrode 210-2 may overlap the sacrificial layer SLY. The width of each of the first pixel electrode 210-1 and the second pixel electrode 210-2 may be the same as the width of the sacrificial layer SLY.

The first-1 conductive opening OPC1-1 may accommodate at least a portion of the first pixel electrode 210-1. The first-2 conductive opening OPC1-2 may accommodate at least a portion of the second pixel electrode 210-2. The width of the first-1 conductive opening OPC1-1 may be greater than the width of the first pixel electrode 210-1. The width of the first-2 conductive opening OPC1-2 may be greater than the width of the second pixel electrode 210-2. Each of the second-1 conductive opening OPC2-1 and the second-2 conductive opening OPC2-2 may accommodate at least a portion of the sacrificial layer SLY. The width of the second-1 conductive opening OPC2-1 and the width of the second-2 conductive opening OPC2-2 may be greater than the width of the sacrificial layer SLY.

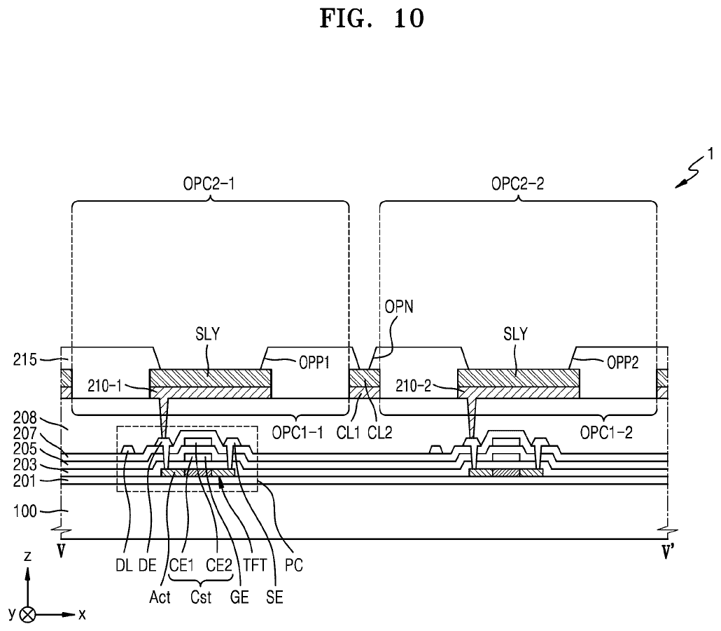

Referring to FIGS. 7 and 10, the method 2 of manufacturing a display device may include an operation S4 of arranging a bank layer 215 on the second conductive layer CL2. For example, the second conductive layer CL2 may include a first pixel opening OPP1, a second pixel opening OPP2, and a connection opening OPN.

For example, the bank layer 215 may be arranged on the planarization layer 208. The bank layer 215 may cover at least portions of the second conductive layer CL2 and the sacrificial layer SLY. Each of the first pixel opening OPP1 and the second pixel opening OPP2 may expose at least a portion of the sacrificial layer SLY. The connection opening OPN may expose at least a portion of the second conductive layer CL2.

The process of forming the first pixel opening OPP1, the second pixel opening OPP2, and the connection opening OPN in the second conductive layer CL2 may be performed by a photolithography process. The bank layer 215 may be performed by wet etching, dry etching, or a combination thereof. A known method may be used as the photolithography process.

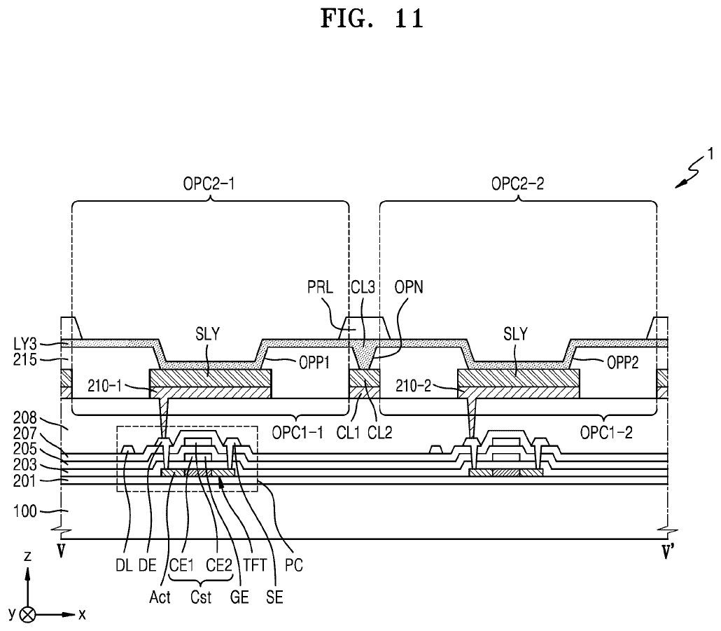

Referring to FIGS. 7 and 11, the method 2 of manufacturing a display device may include an operation S5 of arranging a third layer LY3 on the bank layer 215, and an operation S6 of arranging a photoresist layer PRL on the third layer LY3.

The third layer LY3 may cover (e.g., entirely cover) the substrate 100. The third layer LY3 may be arranged on the bank layer 215, and at least a portion of the third layer LY3 may be accommodated in the first pixel opening OPP1, the second pixel opening OPP2, and the connection opening OPN. The third layer LY3 may be in contact with the sacrificial layer SLY and the second conductive layer CL2. The third layer LY3 may be electrically connected to the second conductive layer CL2.

The third layer LY3 may include the same material as the third conductive layer CL3 described with reference to FIG. 5. For example, the third layer LY3 may include a light-transmitting conductive layer including a light-transmitting conductive oxide, such as ITO, In₂O₃ or IZO, and a reflective layer including a metal, such as Al or Ag. For example, the third layer LY3 may have a three-layered structure including ITO/Ag/ITO layers.

The photoresist layer PRL may be arranged on the third layer LY3 to overlap the connection opening OPN in a plan view. The photoresist layer PRL may include a photosensitive material. For example, the photoresist layer PRL may include an HMDSO material.

Referring to FIGS. 7, 11 and 12, the method 2 of manufacturing a display device may include a third patterning operation S7.

The third patterning operation S7 may be an operation of patterning the third layer LY3 to form a third conductive layer CL3. For example, the third conductive layer CL3 may include a third-1 conductive opening OPC3-1 and a third-2 conductive opening OPC3-2.

A portion of the third layer LY3 that does not overlap the photoresist layer PRL may be etched. The etching of the third layer LY3 may be performed by wet etching, dry etching, or a combination thereof. As the third layer LY3 is etched, the third-1 conductive opening OPC3-1 and the third-2 conductive opening OPC3-2 may be formed.

In a plan view, the third-1 conductive opening OPC3-1 may overlap the first pixel opening OPP1. In a plan view, the third-1 conductive opening OPC3-1 may surround the first pixel opening OPP1. In a plan view, the third-2 conductive opening OPC3-2 may overlap the second pixel opening OPP2. In a plan view, the third-2 conductive opening OPC3-2 may surround the second pixel opening OPP2.

Referring to FIGS. 7, 12, and 13, the method 2 of manufacturing a display device may include an operation S8 of removing the sacrificial layer SLY. As the sacrificial layer SLY is removed, the first pixel electrode 210-1 and the second pixel electrode 210-2 may be exposed. The end of the bank layer 215 defining the first pixel opening OPP1 and the second pixel opening OPP2 may have an undercut structure.

The operation S8 of removing the sacrificial layer SLY may be an operation of etching the sacrificial layer SLY. The etching of the sacrificial layer SLY may be performed by wet etching, dry etching, or a combination thereof. For example, the etching of the sacrificial layer SLY may be performed by wet etching, and the first pixel electrode 210-1 and the second pixel electrode 210-2 may not be etched due to the difference in selectivity between the sacrificial layer SLY and the first and second pixel electrodes 210-1 and 210-2.

Referring to FIGS. 7, 13, and 14, the method 2 of manufacturing a display device may include an operation S9 of removing the photoresist layer PRL. A known method may be used as the process of removing the photoresist layer PRL.

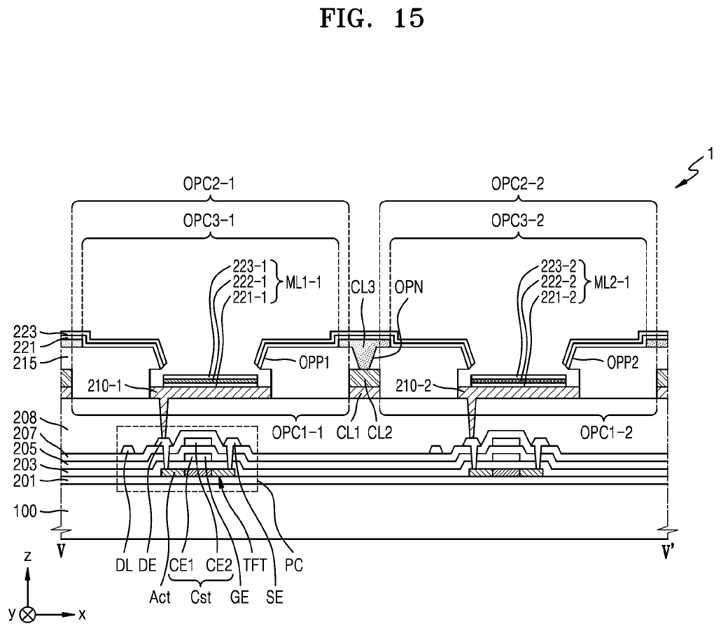

Referring to FIGS. 7 and 15, the method 2 of manufacturing a display device may include an operation S101 of arranging a first-1 intermediate layer ML1-1 on the first pixel electrode 210-1, and an operation S102 of arranging a second-1 intermediate layer ML2-1 on the second pixel electrode 210-2.

A first common layer 221 may be arranged on the bank layer 215. In this process, a first-1 common layer 221-1 may be arranged on the first pixel electrode 210-1, and a second-1 common layer 221-2 may be arranged on the second pixel electrode 210-2. Due to the undercut structure of the bank layer 215, the first-1 common layer 221-1 and the second-1 common layer 221-2 may be spaced apart from each other.

A first-1 emission layer 222-1 may be arranged on the first-1 common layer 221-1, and a second-1 emission layer 222-2 may be arranged on the second-1 common layer 221-2. The first-1 emission layer 222-1 and the second-1 emission layer 222-2 may emit light of different colors. The first-1 emission layer 222-1 and the second-1 emission layer 222-2 may be spaced apart from each other.

A second common layer 223 may be arranged on the first common layer 221. In this process, a first-2 common layer 223-1 may be arranged on the first-1 emission layer 222-1, and a second-2 common layer 223-2 may be arranged on the second-1 emission layer 222-2. Due to the undercut structure of the bank layer 215, the first-2 common layer 223-1 and the second-2 common layer 223-2 may be spaced apart from each other.

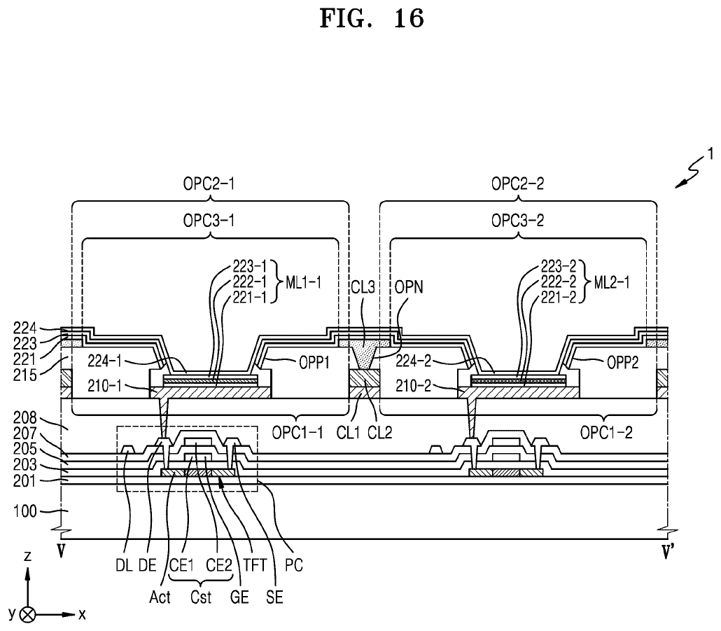

Referring to FIGS. 7 and 16, the method 2 of manufacturing a display device may include an operation S11 of arranging a charge generation layer 224 on the first-1 intermediate layer ML1-1 and the second-1 intermediate layer ML2-1. The charge generation layer 224 may be arranged on the second common layer 223. The charge generation layer 224 may be integrally provided as a single body over the entire substrate 100.

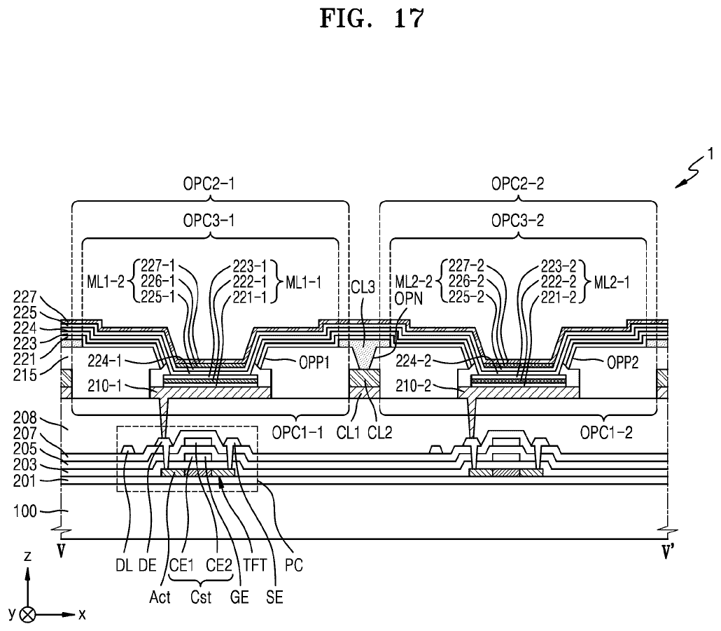

Referring to FIGS. 7 and 17, the method 2 of manufacturing a display device may include an operation S121 of arranging a first-2 intermediate layer ML1-2 on the charge generation layer 224, and an operation S122 of arranging a second-2 intermediate layer ML2-2 on the charge generation layer 224.

A third common layer 225 may be arranged on the charge generation layer 224. In this process, a first-3 common layer 225-1 may be arranged on the first pixel electrode 210-1, and a second-3 common layer 225-2 may be arranged on the second pixel electrode 210-2. The third common layer 225 may be integrally provided as a single body over the entire substrate 100.

A first-2 emission layer 226-1 may be arranged on the first-3 common layer 225-1, and a second-2 emission layer 226-2 may be arranged on the second-3 common layer 225-2. The first-2 emission layer 226-1 and the second-2 emission layer 226-2 may emit light of different colors. The first-2 emission layer 226-1 may emit light of the same color as the first-1 emission layer 222-1, and the second-2 emission layer 226-2 may emit light of the same color as the second-1 emission layer 222-2. The first-2 emission layer 226-1 and the second-2 emission layer 226-2 may be spaced apart from each other.

A fourth common layer 227 may be arranged on the third common layer 225. In this process, a first-4 common layer 227-1 may be arranged on the first-2 emission layer 226-1, and a second-4 common layer 227-2 may be arranged on the second-2 emission layer 226-2. The first-4 common layer 227-1 and the second-4 common layer 227-2 may be integrally formed as a single body over the entire substrate 100.

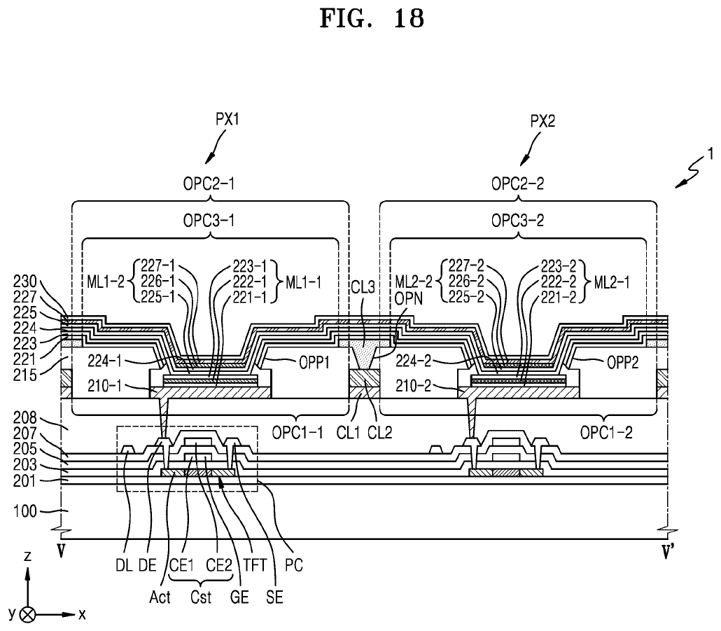

Referring to FIGS. 7 and 18, the method 2 of manufacturing a display device may include an operation S13 of arranging an opposite electrode 230 on the first-2 intermediate layer ML1-2 and the second-2 intermediate layer ML2-2. The opposite electrode 230 may be arranged on the fourth common layer 227. The opposite electrode 230 may be integrally provided as a single body over the entire substrate 100.

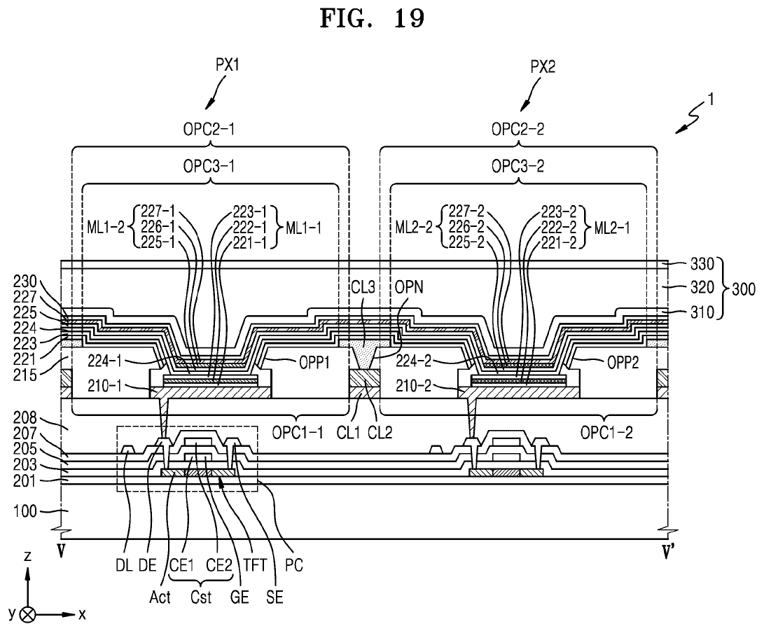

Referring to FIGS. 7 and 19, the method 2 of manufacturing a display device may include an operation S14 of arranging an encapsulation layer 300 on the opposite electrode 230. A first inorganic encapsulation layer 310 may be arranged on the opposite electrode 230. An organic encapsulation layer 320 may be arranged on the first inorganic encapsulation layer 310. A second inorganic encapsulation layer 330 may be arranged on the organic encapsulation layer 320. The encapsulation layer 300 may be integrally provided as a single body over the entire substrate 100.

According to embodiments, the quality and durability of the display device may be improved.

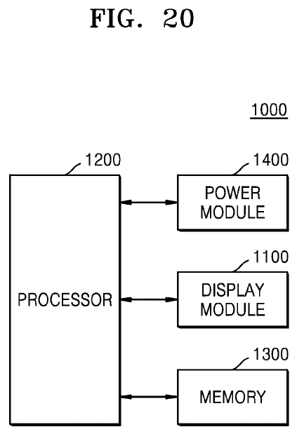

FIG. 20 is a schematic block diagram of an electronic device according to an embodiment.

Referring to FIG. 20, according to an embodiment, an electronic device 1000 may include the display module 1100, a processor 1200, a memory 1300, and a power module 1400.

The processor 1200 may include at least one of a Central Processing Unit (CPU), an Application Processor (AP), a Graphics Processing Unit (GPU), a Communication Processor (CP), an Image Signal Processor (ISP), and a controller.

The memory 15 may store data information necessary for operation of the processor 1200 or the display module 1100. When the processor 1200 executes an application stored in the memory 15, video data signals and/or input control signals may be transmitted to the display module 1100, and the display module 1100 may process the received signals to output video information through a display screen.

The power module 1400 may include a power supply module such as a power adapter or a battery device, and a power conversion module that converts power supplied by the power supply module to generate power necessary for operation of the electronic device 1000.

At least one of the components of the above-described electronic device 1000 may be included in the display device according to the above-described embodiments. Additionally, among individual modules included within one module functionally, some may be included in the display device and others may be provided separately from the display device. For example, the display device may include the display module 1100, and the processor 1200, memory 1300, and power module 1400 may be provided in the form of other devices within the electronic device 1000 that are not the display device.

The display module 1100 of FIG. 20 may refer to one of the examples of the display module 1100 described in FIGS. 1 to 19. While other descriptions are omitted for convenience of description, those skilled in the art may easily and clearly understand the display module 1100 of FIG. 20 from the descriptions of FIGS. 1 to 19.

According to an embodiment, the electronic device 1000 may include the memory 1300 storing data information, the processor 1200 generating data signals and/or control signals based on the data information, and the display module 1100 operating based on the data signals and/or control signals. The display module 1100 may include the substrate 100, the first pixel electrode 140-1 and the second pixel electrode 140-1 disposed on the substrate 100, the pixel defining layer 105 covering edges of each of the first pixel electrode 140-1 and the second pixel electrode 140-2 to define the first emission region E1 and the second emission region E2, and the conductive structure STB disposed between the first pixel electrode 140-1 and the second pixel electrode 140-2 on the pixel defining layer 105. The display module 1100 may further include the first intermediate layer 150-1 covering the first emission region E1 and the portion of the conductive structure STB, the second intermediate layer 150-2 covering the second emission region E2 and the portion of the conductive structure STB, the first counter electrode 160-1 covering the first intermediate layer 150-1 and directly contacting the conductive structure STB, and the second counter electrode 160-2 covering the second intermediate layer 150-2 and directly contacting the conductive structure STB.

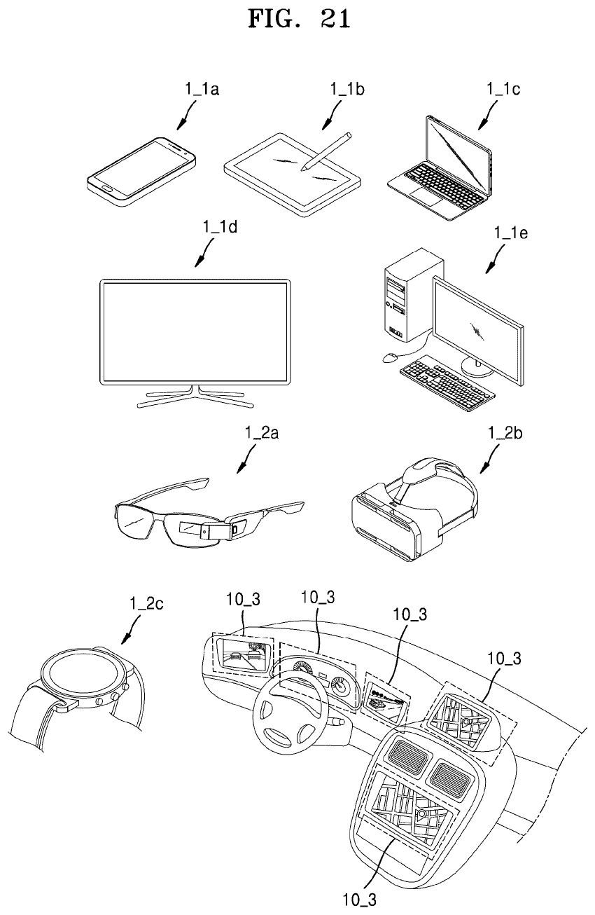

FIG. 21 is schematic views of electronic devices according to various embodiments.

Referring to FIG. 21, various electronic devices to which the display device according to the embodiments may be applied may include not only image display electronic devices such as smartphones 10_1a, tablet PCs 10_1b, laptops 10_1c, TVs 10_1d, and desktop monitors 10_1e, but also wearable electronic devices including display modules such as smart glasses 10_2a, head mounted displays 10_2b, and smart watches 10_2c, and vehicular electronic devices 10_3 including display modules such as instrument panels, center fascias, Center Information Displays (CID) disposed on dashboards, and room mirror displays of automobiles. It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a first pixel electrode and a second pixel electrode, which are arranged on the substrate to be spaced apart from each other;
a first conductive layer, which is arranged on the substrate and includes a first-1 conductive opening that accommodates at least a portion of the first pixel electrode and a first-2 conductive opening that accommodates at least a portion of the second pixel electrode;
a second conductive layer, which is arranged on the first conductive layer and includes a second-1 conductive opening that overlaps the first-1 conductive opening and a second-2 conductive opening that overlaps the first-2 conductive opening;
a bank layer, which is arranged on the second conductive layer and includes a first pixel opening that exposes at least a portion of the first pixel electrode, a second pixel opening that exposes at least a portion of the second pixel electrode, and a connection opening that exposes at least a portion of the second conductive layer; and
a third conductive layer arranged on the bank layer and electrically connected to the second conductive layer through the connection opening.

2. The display device of claim 1, further comprising:
a first-1 intermediate layer arranged on the first pixel electrode;
a first charge generation layer arranged on the first-1 intermediate layer;
a first-2 intermediate layer arranged on the first charge generation layer;
a second-1 intermediate layer arranged on the second pixel electrode;
a second charge generation layer arranged on the second-1 intermediate layer;
a second-2 intermediate layer arranged on the second charge generation layer; and
an opposite electrode arranged on the first-2 intermediate layer and the second-2 intermediate layer.

3. The display device of claim 2, wherein the first-1 intermediate layer is spaced apart from the first-2 intermediate layer.

4. The display device of claim 2, wherein the first charge generation layer is electrically connected to the second charge generation layer.

5. The display device of claim 1, wherein an end of the bank layer defining the first pixel opening includes an undercut structure.

6. The display device of claim 1, wherein, in a cross-sectional view, the connection opening is arranged between the first pixel opening and the second pixel opening.

7. The display device of claim 1, wherein the third conductive layer includes a third-1 conductive opening and a third-2 conductive opening,
in a plan view, the third-1 conductive opening surrounds the first pixel opening, and
in a plan view, the third-2 conductive opening surrounds the second pixel opening.

8. The display device of claim 1, wherein the first conductive layer is electrically connected to a common voltage supply line.

9. The display device of claim 1, wherein the first conductive layer is electrically connected to at least one of the first pixel electrode and the second pixel electrode.

10. An electronic device comprising:
a substrate;
a first pixel electrode and a second pixel electrode, which are arranged on the substrate to be spaced apart from each other;
a first conductive layer, which is arranged on the substrate and includes a first-1 conductive opening that accommodates at least a portion of the first pixel electrode and a first-2 conductive opening that accommodates at least a portion of the second pixel electrode;
a second conductive layer, which is arranged on the first conductive layer and includes a second-1 conductive opening that overlaps the first-1 conductive opening and a second-2 conductive opening that overlaps the first-2 conductive opening;
a bank layer, which is arranged on the second conductive layer and includes a first pixel opening that exposes at least a portion of the first pixel electrode, a second pixel opening that exposes at least a portion of the second pixel electrode, and a connection opening that exposes at least a portion of the second conductive layer; and
a third conductive layer arranged on the bank layer and electrically connected to the second conductive layer through the connection opening.

11. A method of manufacturing a display device, the method comprising:
arranging a first layer on a substrate;
arranging a second layer on the first layer;
patterning the first layer to form a first pixel electrode, a second pixel electrode, and a first conductive layer including a first-1 conductive opening and a first-2 conductive opening;
patterning the second layer to form a second conductive layer including a second-1 conductive opening and a second-2 conductive opening and a sacrificial layer;
arranging, on the second conductive layer, a bank layer including a first pixel opening, a second pixel opening, and a connection opening;
arranging, on the bank layer, a third layer, at least a portion of which is accommodated in the connection opening;
arranging, on the third layer, a photoresist layer overlapping the connection opening;
patterning the third layer to form a third conductive layer including a third-1 conductive opening and a third-2 conductive opening;
removing the sacrificial layer; and
removing the photoresist layer.

12. The method of claim 11, wherein
the patterning of the first layer and the patterning of the second layer are simultaneously performed,
the first-1 conductive opening overlaps the second-1 conductive opening and accommodates at least a portion of the first pixel electrode, and
the first-2 conductive opening overlaps the second-2 conductive opening and accommodates at least a portion of the second pixel electrode.

13. The method of claim 11, further comprising:
arranging a first-1 intermediate layer on the first pixel electrode;
arranging a second-1 intermediate layer on the second pixel electrode;
arranging a charge generation layer on the first-1 intermediate layer and the second-1 intermediate layer;
arranging a first-2 intermediate layer on the charge generation layer to overlap the first pixel electrode;
arranging a second-2 intermediate layer on the charge generation layer to overlap the second pixel electrode; and
arranging an opposite electrode on the first-2 intermediate layer and the second-2 intermediate layer.

14. The method of claim 13, wherein an opposite electrode overlapping the first pixel electrode is electrically connected to an opposite electrode overlapping the second pixel electrode.

15. The method of claim 13, wherein, in a plan view, the first-1 intermediate layer and the second-1 intermediate layer are spaced apart from each other.

16. The method of claim 13, wherein a charge generation layer overlapping the first pixel electrode is electrically connected to a charge generation layer overlapping the second pixel electrode.

17. The method of claim 11, wherein the third conductive layer is electrically connected to the second conductive layer through the connection opening.

18. The method of claim 11, wherein, in a plan view, the third-1 conductive opening is arranged to surround the first pixel opening, and the third-2 conductive opening is arranged to surround the second pixel opening.

19. The method of claim 11, wherein the first conductive layer is electrically connected to a common voltage supply line.

20. The method of claim 11, wherein the first conductive layer is electrically connected to at least one of the first pixel electrode and the second pixel electrode.
